(19) United States
(12) Patent Application Publication
(10) Pub. No.: US 2007/0063330 A1
(43) Pub. Date: Mar. 22, 2007

(54) Complex laminated chip element

(76) Inventors: In-Kil Park, Suwon (KR); Soon-Ha Hwang, Seoul (KR); Duk-Hee Kim, Gunpo (KR)

Correspondence Address: MARGER JOHNSON & MCCOLLOM, P.C., 210 SW MORRISON STREET, SUITE 400, PORTLAND, OR, 97204, US

(21) Appl. No.: 10/566,810

(22) PCT Filed: Jul. 15, 2004
(86) PCT No.: PCT/KR04/01759

§ 371 Date: Sep. 21, 2006

(30) Foreign Application Priority Data
Jul. 30, 2003 (KR) 10 2003-0052561
Jul. 30, 2003 (KR) 10 2003 0052562

(51) Int. Cl. H01L 23/02

(52) U.S. Cl. 257/686

(57) ABSTRACT

The present invention relates to a laminated chip element which can be manufactured to have desired electric properties by combining various elements in accordance with the desired objectives. More particularly, the present invention relates to a laminated chip element which has superior high frequency properties and can be manufactured to control capacitance and/or inductance of the laminated chip element to a desired value. There is provided a laminated chip element, comprising at least one first sheet on which first and second conductive patterns are formed, the first and second conductive patterns being spaced apart from each other in a direction of both ends of the first sheet; and at least one second sheet on which a third conductive pattern is formed, the third conductive pattern being formed in a transverse direction of both the ends of the first sheet; wherein one ends of the first and second conductive patterns are connected to the first and second external terminals, respectively, at least one end of the third conductive pattern is connected to a third external terminal, and the first and second sheets are laminated. There is also provided a laminated chip element, comprising: at least one first sheet on which a conductive pattern is formed, the first conductive pattern consisting of first and third portions, the first and second portions being spaced apart from each other in a direction of both ends of the first sheet, the second portion connecting the first and second portions to each other to have a predetermined inductance; and at least one second sheet on which a conductive pattern is formed in a transverse direction of both the ends of the first sheet; wherein the first and second portions are connected to the first and second external terminals, respectively, at least one ends of the second conductive pattern is connected to a third external terminal, and the first and second sheets are laminated.

### TECHNICAL FIELD

The present invention relates to a laminated chip element which can be manufactured to have desired electric properties by combining various elements in accordance with the desired objectives. More particularly, the present invention relates to a laminated chip element which has superior high frequency properties and can be manufactured to control capacitance and/or inductance of the laminated chip element to a desired value. The present invention also relates to a laminated chip element manufactured by combining varistors, resistors and/or inductors in order to protect semiconductor integrated circuits and main electronic parts against over-voltage and static electricity conditions.

### BACKGROUND ART

Resistors (R), capacitors (C) and inductors (L) are typical passive elements in electronic circuits, whose functions and roles are very diverse.

The resistors control the flow of current in the circuits and also function to effect impedance matching in alternating current circuits. The capacitors essentially prevent the flow of direct current but allow the flow of alternating currents. In addition, the capacitors are employed in time constant circuits, time delay circuits, and RC and LC filter circuits and may function to remove noise. The inductors may be combined with the capacitors so that they embody all sorts of filters. Such filters remove noise or selectively reject signals of certain frequencies while allowing others to pass.

Generally, since varistors cause resistance thereof to vary according to an applied voltage, the varistors are widely used as protection elements for protecting main electronic parts and circuits from over-voltage (surge voltage) and static electricity conditions. Current, in other words, does not flow in the varistor in normal state. However, if over-voltage over a predetermined value is applied to both terminals of the varistor by a thunderbolt or the like, the resistance of the varistor is rapidly reduced. Thus, the current mostly flows in the varistor and does not flow in any other elements so that the circuit is protected from the over-voltage. Given the recent miniaturization of electronic machines, such varistors tend to be minimized and in the form of arrays in order to protect large integrated circuit chip elements and the like from static electricity and over-voltage.

In addition, the varistor functions as a capacitor in the normal state when over-voltage is not applied. Such a capacitor has a property to allow a signal to pass only when a current or voltage between separate electrodes changes. The capacitor, however, not only has capacitance but also parasitic inductance. In the same manner, the inductor, which not only has inductance but also parasitic capacitance, can also protect a current from varying when the current flows in a wire. As a result, the function of the element is changed at a predetermined frequency, which is referred to as a self-resonant frequency.

With such a varistor combined with the resistor, a stable operation of electronic devices is secured since the main electronic parts or circuits can be effectively protected from the over-voltage and the noise can also be removed.

When over-voltage is not applied, a varistor combined with a resistor functions as a capacitor combined with a resistor. In addition, a varistor combined with an inductor may be formed in a pi-shaped (π-shaped) filter including inductors and capacitors, which has a preferred property of removing high frequency noise. If over-voltage is introduced into the circuit, the varistor combined with the resistor or the varistor combined with the inductor functions as a varistor, and then, protects the circuit from the over-current. Generally, the appropriate combination of the resistors, inductors and capacitors as typical passive elements may perform impedance matching, remove high and/or low frequency noise or select a signal with a certain frequency range in the circuit.

If the passive elements are combined by wires so as to form the combined element in the electronic circuit, equivalent series inductance and resistance change in accordance to the length of the wires because the wires in which the current flows elongate. Therefore, the flow of high frequency current is often prevented, and insertion loss occurs due to electric power consumption of the respective elements. For such reasons, complex laminated chip elements have been developed by combining various elements.

FIG. 35 is a view showing the manufacturing process of a laminated chip element according to a prior art wherein four capacitor elements are manufactured into a single chip element. FIGS. 36 and 37 are sectional and plane views of the conventional laminated chip element, respectively. Referring to FIG. 35, four first conductive patterns 1410 are formed in parallel with each other on a first sheet 1401, wherein each of the first conductive patterns 1410 is formed within a range of each unit element in a direction of both opposite ends thereof. Both ends of each of the first conductive patterns 1410 of the first sheet 1401 are extended to be connected to a first external terminal 1430 and a second external terminal 1431, which are used as input and output terminals, respectively. A second sheet 1402 is formed with a second conductive pattern 1411 across the first conductive patterns 1410, wherein both ends of the second sheet 1402 are extended to be connected to a third external terminal 1432, which is used as a common terminal (ground). After laminating and compressing the sheets and cutting the laminate to a proper size, the laminate is sintered, causing the respective sheets to be manufactured into an element body. As shown in FIG. 35 (b), the first and second conductive patterns 1410 and 1411 of the element body are formed so that the ends of the first and second conductive patterns 1410 and 1411 are exposed to respective outer surfaces of the element body. Then, as shown in FIG. 35 (c), the chip element is completed by forming the first, second and third external terminals 1430, 1431 and 1432 on the outer surfaces of the element body in order to connect the external terminals to the corresponding ends of the first and second conductive patterns 1410 and 1411, respectively. At this time, a segment divided by imaginary lines (two-dot chain lines) in the figure operates as a unit element.

FIG. 36 is a sectional view taken along a line B-B of the chip element, completed according to the manufacturing process shown in FIG. 35. FIG. 37 is a plane view of the completed chip element. The capacitor is an electric element used to store electrical charge when a voltage is applied, consisting in general of two conductors (electrodes) separated and insulated from each other by a dielectric. Referring to FIG. 36, the first conductive pattern 1410 and the second conductive pattern 1411 are separated from each other by the thickness of the sheet. Referring to FIG. 37, the first conductive pattern 1410 overlaps with the second conductive pattern 1411 by an overlapping portion 1440. Its capacitance is directly proportional to the area of the overlapping portion 1440 and inversely proportional to the thickness of the sheet.

The laminated chip element may be expressed as an equivalent circuit diagram of FIG. 38. Contrary to a two-terminal laminated chip, the laminated chip shown in FIG. 35 to FIG. 38 has a particular internal electrode structure in that currents flowing in the first and second conductive patterns 1410 and 1411 cross each other at 90 degrees, which is referred to as a feedthrough capacitor.

FIG. 39 shows frequency properties when such a three-terminal feedthrough capacitor is used as a low pass filter (a) and when a general capacitor is used as a low pass filter (b), respectively. As shown in the figure, the feedthrough capacitor has a high self-resonant frequency compared to that of the general capacitor. Since all the input and output signal terminals and the ground terminal are compactly formed in the single chip element, high insertion loss with respect to the high frequency noise can be achieved. Thus, in practice, the three-terminal, feedthrough laminated chip elements have been widely used in electronic circuits.

It is, however, difficult for the conventional laminated chip element to perform impedance matching, remove high and low frequency noise or select a signal with a certain frequency range. It is also not easy for users to control the capacitance, resistance, and inductance to the desired values. Therefore, there are difficulties in manufacturing the elements suitable for the required frequency properties.

In addition, since the manufacturing process of the conventional laminated chip element is complicated and difficult, it is difficult to manufacture the complex chip by combining different kinds of elements and to integrate a plurality of unit elements into a single chip in an array.

### DISCLOSURE OF INVENTION

### Technical Problem

The present invention is conceived to solve the problems in the related art. An object of the present invention is to provide a laminated chip element, which has improved frequency properties, for example, the noise removal, insertion loss and the like.

Another object of the present invention is to provide a laminated chip element, which can be manufactured to have capacitance, resistance and inductance of desired values according to the desired objectives of the element.

An additional object of the present invention is to provide a laminated chip element, which protects main electronic parts such as semiconductor integrated circuits from over-voltage and static electricity conditions.

A further object of the present invention is to provide a laminated chip element, which is minimized by manufacturing it in an array that is formed by arranging a plurality of required elements into a single chip without additional processes.

### Technical Solution

According to an aspect of the present invention for achieving the objects, there is provided a laminated chip element, comprising: at least one first sheet on which first and second conductive patterns are formed, the first and second conductive patterns being spaced apart from each other in a direction of both ends of the first sheet; and at least one second sheet on which a third conductive pattern is formed, the third conductive pattern being formed in a transverse direction of both the ends of the first sheet; wherein one ends of the first and second conductive patterns are connected to first and second external terminals, respectively, at least one end of the third conductive pattern is connected to a third external terminal, and the first and second sheets are laminated.

According to another aspect of the present invention for achieving the objects, there is provided a laminated chip element, comprising: at least one first sheet on which first and second conductive patterns are formed, the first and second conductive patterns being spaced apart from each other in a direction of both ends of the first sheet; and at least one second sheet on which a third conductive pattern is formed, the third conductive pattern consisting of first and second portions which are spaced apart from each other and formed in a transverse direction of both the ends of the first sheet; wherein one ends of the first and second conductive patterns are connected to first and second external terminals, respectively, both opposite ends of the first and second portions of the third conductive pattern are connected to third and fourth external terminals, respectively, and the first and second sheets are laminated.

The first and second sheets may be alternately laminated on each other. Two of the second sheets may be laminated adjacent to each other.

According to a further aspect of the present invention for achieving the objects, there is provided a laminated chip element, comprising: at least one first sheet on which a first conductive pattern is formed in a direction of both ends of the first sheet; and at least one second sheet on which a second conductive pattern is formed in the same direction of the first conductive pattern, at least one third sheet on which a third conductive pattern is formed in a transverse direction of both the ends of the first sheet; wherein one ends of the first and second conductive patterns are connected to first and second external terminals, respectively, at least one end of the third conductive pattern is connected to a third external terminal, and the first to third sheets are laminated.

Two of the second sheets may be laminated adjacent to each other. Preferably, the laminated chip element further comprises at least one second sheet on which a second conductive pattern is formed in the same direction of the first conductive pattern, wherein an end of the second conductive pattern is connected to a second external terminal, and the first to third sheets are laminated. The first to third sheets may be laminated so that one or more of the third sheets are interposed between the first sheet and the second sheet.

According to an additional aspect of the present invention for achieving the objects, there is provided a laminated chip element, comprising: at least one first sheet on which a first conductive pattern is formed in a direction of both ends of the first sheet; at least one second sheet on which a second conductive pattern is formed in the same direction of the first conductive pattern; at least one third sheet on which a third conductive pattern is formed in a transverse direction both the ends of the first sheet; and at least one fourth sheet on which a fourth conductive pattern is formed in the same direction of the third conductive pattern; wherein both opposite ends of the first and second conductive patterns are connected to first and second external terminals, respectively, both opposite ends of the third and fourth conductive patterns are connected to third and fourth external terminals, respectively, and the first to fourth sheets are laminated.

The third and fourth sheets may be interposed between the first sheet and the second sheet.

According to a further additional aspect of the present invention for achieving the objects, there is provided a laminated chip element, comprising: at least one first sheet on which a first conductive pattern is formed in a direction of both ends of the first sheet; at least one second sheet on which a second conductive pattern is formed in the same direction of the first conductive pattern; and at least one third sheet on which a third conductive pattern is formed in the same direction of the first conductive pattern; wherein both opposite ends of the first and second conductive patterns are connected to first and second external terminals, respectively, an end of the third conductive pattern is connected to a third external terminal, and the first to third sheets are laminated.

A first laminate consisting of two of the first sheets and one of the third sheets interposed between the two first sheets and a second laminate consisting of two of the second sheets and one of the third sheets interposed between the two second sheets may be laminated on each other. One or more of the third sheets may be interposed between the first sheet and the second sheet.

According to a still further aspect of the present invention for achieving the objects, there is provided a laminated chip element, comprising: at least one first sheet on which a first conductive pattern is formed, the first conductive pattern consisting of first to third portions, the first and second portions being spaced apart from each other in a direction of both ends of the first sheet, the third portion being spaced apart from the first and second portions and formed in a transverse direction of both the ends of the first sheet; and at least one second sheet on which a second conductive pattern is formed, the second conductive pattern consisting of fourth and fifth portions, the fourth portion partially overlapping with the first and third portions, the fifth portion partially overlapping with the second and third portions; wherein one ends of the first and second portions are connected to first and second external terminals, respectively, at least one end of the third portion is connected to a third external terminal, and the first and second sheets are laminated. The first and second sheets may be alternately laminated on each other.

In the previous laminated chip elements, areas of overlapping portions between the conductive patterns may differ from each other.

In the previous laminated chip elements, preferably, a resistive pattern is formed on the laminated chip element, and both ends of the resistive pattern are connected to the first and second external terminals, respectively. In such a case, two metal pads may be formed in spaced relation with each other, and the resistive pattern may be formed so that the resistive pattern connects the two metal pads to each other. An insulated pattern or layer may be formed on the uppermost one of the laminated sheets. A resistive pattern may comprise resistive material, such as Ni—Cr or RuO₂. Alternatively, the chip element according to the previous aspects may further comprise at least one resistor sheet on each of which a resistive pattern is armed, wherein said at least one resistor sheet is further laminated.

In the previous laminated chip elements, preferably, an inductive pattern is formed on the laminated chip element, and both ends of the inductive pattern are connected to the first and second external terminals, respectively. More preferably, the inductive pattern is spiral, an insulated bridge is formed in a radial direction across the spiral inductive pattern, and a bridge pattern for extending a center end of the inductive pattern to an outside thereof is formed on the insulated bridge. Still preferably, a ferrite layer is form on the laminated chip element, and the inductive pattern is formed on the ferrite layer. The inductive pattern may comprise metal material, such as Ag, Pt, Pd. Also, the inductive pattern may comprise resistive material, such as Ni—Cr, RuO₂. Two metal pads may be formed in spaced relation with each other, and the inductive pattern is formed so that the inductive pattern connects the two metal pads to each other. An insulated pattern or layer may be formed on the uppermost one of the laminated sheets.

A plurality of the laminated chip elements according to the previous aspects may be arranged in parallel with each other and integrally manufactured in an array. That is, a plurality of the conductive patterns which are formed in the direction of both the opposite ends of the corresponding sheets are formed in parallel with each other so that a plurality of unit elements are integrally manufactured into the laminated chip element in an array, the conductive pattern which is formed in the transverse direction of both the opposite ends of the corresponding sheet being formed to extend over the unit elements. Preferably, inductive patterns for some of said plurality of the laminated chip elements are formed on an upper surface of the laminated chip element, inductive patterns for the others of said plurality of the laminated chip elements are formed on a lower surface of the laminated chip element, and both ends of the respective inductive patterns are connected to the corresponding first and second external terminals. Still preferably, a plurality of inductor sheets are further laminated, at least one inductive pattern is armed on each of the inductor sheets, and both ends of the respective inductive patterns are connected to the corresponding first and second external terminals. In such a case, the inductive pattern nay be meander-shaped.

In the previous laminated chip elements, preferably, a plurality of inductor sheets are further laminated, an inductive pattern is formed on each of the inductor sheets, the inductive patterns are connected to each other in series through holes formed in the inductor sheets, both ends of the connected inductive patterns are connected to the first and second external terminals, respectively. More preferably, the through holes are filled with conductive material in order to connect the inductive patterns to each other. In such a case, the inductor sheets may comprise a first inductor sheet on which a first inductive pattern is formed, one end of the first inductive pattern being extended to an edge of the first inductor sheet, a through hole being formed at the other end of the first inductive pattern; a second inductor sheet on which a second inductive pattern is formed, one end of the second inductive pattern being extended to an edge of the second inductor sheet, a through hole being formed at the other end of the second inductive pattern; and at least one third inductor sheet on which a third inductive pattern is formed, a through hole being formed at each of both ends of the third inductive pattern; wherein the third inductor sheet is interposed between the first and second inductor sheets, the through holes are filled with conductive material, said one ends of the first and second inductive patterns are connected to the first and second external terminals, respectively, and the first to third inductive patterns are connected to each other through the conductive material filled in the through holes. Also, the inductive patterns nay be formed in the direction of the first and second external terminals. A plurality of such laminated chip elements may be arranged in parallel with each other and integrally manufactured in an array. That is, a plurality of the conductive patterns which are formed in the direction of both the opposite ends of the corresponding sheets are formed in parallel with each other so that a plurality of unit elements are integrally manufactured into the laminated chip element in an array, the conductive pattern which is formed in the transverse direction of both the opposite ends of the corresponding sheet being formed to extend over the unit elements.

According to a still further aspect of the present invention for achieving the objects, there is provided a laminated chip element, comprising: at least one first sheet on which a first conductive pattern is formed, the first conductive pattern consisting of first to third portions, the first and second portions being spaced apart from each other in a direction of both ends of the first sheet, the second portion connecting the first and second portions to each other to have a predetermined inductance; and at least one second sheet on which a second conductive pattern is formed in a transverse direction of both the ends of the first sheet; wherein the first and second portions are connected to first and second external terminals, respectively, at least one ends of the second conductive pattern is connected to a third external terminal, and the first and second sheets are laminated. Preferably, a plurality of the first sheets and the second sheets are alternately laminated on each other, and the first and second portions of the first conductive patterns formed on the respective first sheets are connected to the respective first and second external terminals.

According to a still further aspect of the present invention for achieving the objects, there is provided a laminated chip element, comprising: at least one first sheet on which a first conductive pattern is formed in a direction of both ends of the first sheet; and at least one second sheet on which a second conductive pattern is formed in the same direction of the first conductive pattern; wherein both ends of the first conductive pattern are connected to first and second external terminals, respectively, a terminal connecting portion of the second conductive pattern is connected to a third external terminal, and the first and second sheets are laminated. The terminal connecting portion may be an end of the second conductive pattern. The terminal connecting portion may be an intermediate portion of the second conductive pattern. The terminal connecting portion nay be both opposite ends of the second conductive pattern. In such a case, preferably, a plurality of the first and second conductive patterns are formed in parallel with each other on the corresponding sheets so that a plurality of unit elements are integrally manufactured into the laminated chip element, the terminal connecting portions of two outermost ones of the second conductive patterns are connected to the third external terminal, the terminal connecting portions of the other second conductive patterns are connected to the terminal connecting portions of the adjacent second conductive patterns one to one, and both ends of each of the first conductive patterns are connected to the first and second external terminals for each unit element. One or more of the second sheets may be interposed between two of the first sheets.

Preferably, in the previous laminated chip elements, the sheets comprise ferrite sheets, ceramic sheets, varistor sheets, PTC thermistor sheets, or NTC thermistor Sheets. Also, the conductive patterns may comprise metal material, such as Ag, Pt, Pd. Some of the conductive pattern may comprise resistive material, such as Ni—Cr, RuO₂.

### DESCRIPTION OF DRAWINGS

The above and other objects, features and advantages of the present invention will become apparent from the following description of preferred embodiments given in conjunction with the accompanying drawings, in which:

FIG. 1 is a view showing a manufacturing process of a laminated chip element according to an embodiment 1 of the present invention;

FIG. 2 is a sectional view of the laminated chip element according to the embodiment 1 of the present invention;

FIG. 3 is an equivalent circuit diagram of the laminated chip element according to the embodiment 1 of the present invention;

FIG. 4 is a graph showing a frequency property of the laminated chip element according to the embodiment 1 of the present invention;

FIG. 5 is a view showing a manufacturing process of a laminated chip element according to an embodiment 2 of the present invention;

FIG. 6 is a sectional view of the laminated chip element according to the embodiment 2 of the present invention;

FIG. 7 is a view showing a manufacturing process of a laminated chip element according to an embodiment 3 of the present invention;

FIG. 8 is a view showing a manufacturing process of a laminated chip element according to an embodiment 4 of the present invention;

FIG. 9 is a sectional view of the laminated chip element according to the embodiment 4 of the present invention;

FIG. 10 is a view showing a manufacturing process of a laminated chip element according to an embodiment 5 of the present invention;

FIG. 11 is a graph showing a frequency property of the laminated chip element according to the embodiment 5 of the present invention;

FIG. 12 is a view showing a manufacturing process of a laminated chip element according to an embodiment 6 of the present invention;

FIG. 13 is an equivalent circuit diagram of the laminated chip element according to the embodiment 6 of the present invention;

FIG. 14 is a view showing a manufacturing process of a laminated chip element according to an embodiment 7 of the present invention;

FIG. 15 is a plane view of the laminated chip element according to the embodiment 7 of the present invention;

FIG. 16 is an equivalent circuit diagram of the laminated chip element according to the embodiment 7 of the present invention;

FIG. 17 is a perspective view of a modified laminated chip element according to the embodiment 7 of the present invention;

FIG. 18 is a perspective view of another modified laminated chip element according to the embodiment 7 of the present invention;

FIG. 19 is a view showing a manufacturing process of a laminated chip element according to an embodiment 8 of the present invention;

FIG. 20 is a view showing a manufacturing process of a laminated chip element according to an embodiment 9 of the present invention;

FIG. 21 is an exploded perspective view of a modified laminated chip element according to the embodiment 9 of the present invention;

FIG. 22 is a view showing a manufacturing process of a laminated chip element according to an embodiment 10 of the present invention;

FIG. 23 is an equivalent circuit diagram of the laminated chip element according to the embodiment 10 of the present invention;

FIG. 24 is a graph showing frequency properties of the laminated chip element according to the embodiment 10 of the present invention and a laminated chip element according to a prior art;

FIG. 25 is a view showing a manufacturing process of a laminated chip element according to an embodiment 11 of the present invention;

FIG. 26 is an equivalent circuit diagram of the laminated chip element according to the embodiment 11 of the present invention;

FIG. 27 is a view for explaining an operation of the laminated chip element according to the embodiment 11 of the present invention;

FIG. 28 is a graph showing frequency properties of the laminated chip element according to the embodiment 11 of the present invention and the laminated chip element according to the prior art;

FIG. 29 is a view showing a manufacturing process of a laminated chip element according to an embodiment 12 of the present invention;

FIG. 30 is a view for explaining an operation of the laminated chip element according to the embodiment 12 of the present invention;

FIG. 31 is a graph showing frequency properties of the laminated chip element according to the embodiment 12 of the present invention and the laminated chip element according to the prior art;

FIG. 32 is a view showing a manufacturing process of a laminated chip element according to an embodiment 13 of the present invention;

FIG. 33 is a view for explaining an operation of the laminated chip element according to the embodiment 13 of the present invention;

FIG. 34 is a graph showing frequency properties of the laminated chip element according to the embodiment 13 of the present invention and the laminated chip element according to the prior art;

FIG. 35 is a view showing a manufacturing process of the laminated chip element according to the prior art;

FIG. 36 is a sectional view of the laminated chip element according to the prior art;

FIG. 37 is a plane view of the laminated chip element according to the prior art;

FIG. 38 is an equivalent circuit diagram of the laminated chip element according to the prior art; and

FIG. 39 is a graph showing a frequency property of the laminated chip element according to the prior art.

### BEST MODE

Hereinafter, preferred embodiments of the present invention will be described in detail with reference to the accompanying drawings.

### Embodiment 1

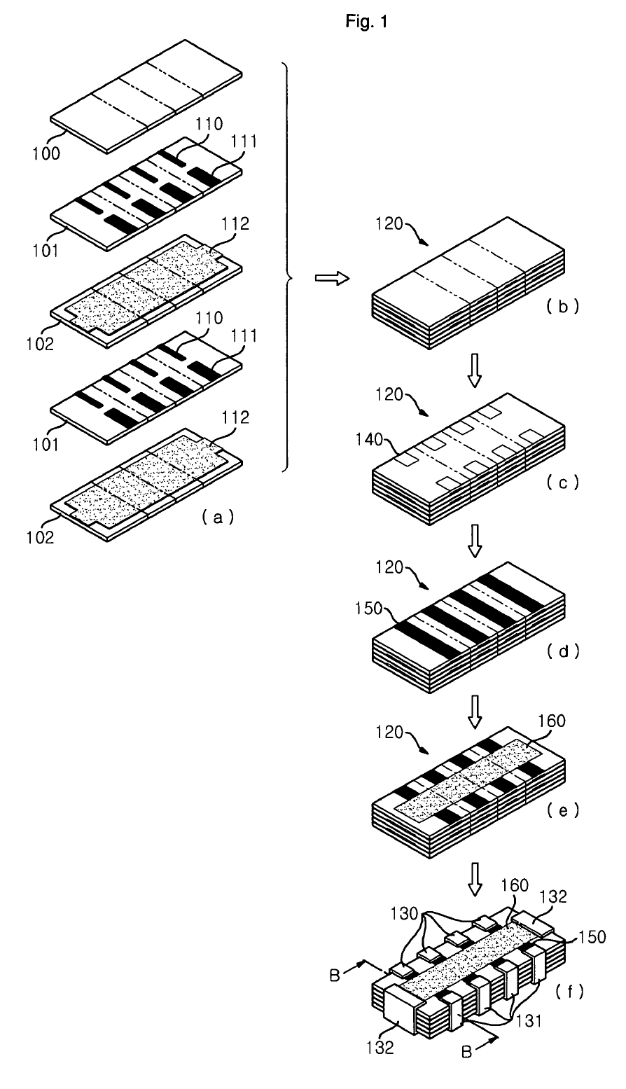

FIGS. 1 to 4 show a structure of a laminated chip element according to the embodiment 1 of the present invention.

FIG. 1 is a view showing a manufacturing process of the laminated chip element according to the embodiment 1 of the present invention, wherein a plurality of elements, for example, four unit elements are integrally manufactured into a single chip element.

First, green sheets for a desired element are manufactured. If a varistor is manufactured, raw material powder for a varistor which is commercially available may be used. Otherwise, the raw material powder may be provided by mixing ZnO powder and additives, such as Bi₂O₃, CoO, MnO, with a solvent, such as water or alcohol, and by milling the mixture for about 24 hours with a ball mill. In order to prepare the green sheets, slurry is produced by mixing PVB-based binder as an additive with the powder for the varistor provided as above, by dissolving the mixture in toluene/alcohol-based solvent, and by milling it for about 24 hours with a small ball mill. Green sheets 100 to 102 having a desired thickness are manufactured from the slurry by using a doctor blade or the like, as shown in FIG. 1. Also, raw material powders for a capacitor, positive temperature coefficient (PTC) thermistor, or negative temperature coefficient (NTC) thermistor may be used to manufacture corresponding green sheets with a desired thickness by the same method described above.

Conductive patterns are formed on the green sheets by printing the conductive patterns with conductive paste of Ag, Pt, Pd or the like, for example, by a screen printing method using screens of internal electrode patterns that are previously designed. That is, first and second conductive patterns 110 and 111 are formed on the first sheet 101 so that the first and second conductive patterns 110 and 111 are spaced apart from each other in a direction of both opposite ends of the sheet 101. A third conductive pattern 112 is formed on the second sheet 102 in a transverse direction of both the opposite ends of the first sheet 101. The first and second conductive patterns 110 and 111 may be formed so that widths thereof are different from each other.

When a plurality of unit elements, for example, four unit elements are integrally formed in a single chip element, a plurality of pairs of the first and second conductive patterns 110 and 111 are formed in parallel with each other so that each pair of the first and second conductive patterns 110 and 111 are arranged within a range of each of the unit elements, into which the chip element are divided by two-dot chain lines. The third conductive pattern 112 connected to a common electrode is formed to extend over the unit elements. In addition, an end of the first conductive pattern 110 and an end of the second conductive pattern 111 are exposed to outer surfaces of the laminated element to be connected to first and second external terminals 130 and 131, respectively. Both opposite ends of the third conductive pattern 112 are exposed to outer surfaces of the laminated element to be connected to a third external terminal 132. Alternatively, any one end of the third conductive pattern 112 may be exposed to an outer surface of the laminated element to be connected to the third external terminal 132. The other ends of the conductive patterns which are not to be connected to the external terminals may be not exposed outside of the laminated element.

Two of the first sheets 101 and two of the second sheets 102, each of which the corresponding conductive patterns are formed on, are alternately laminated on each other, and then, a dummy sheet 100 on which no conductive pattern is armed is laminated thereon, as shown in FIG. 1. In addition, in order to have desired capacitance, although the first and second sheets 101 and 102 are alternately laminated on each other in the present embodiment, a plurality of the first and second sheets 101 and 102 may be laminated in various combinations. That is, by controlling the number of laminations of the first and second sheets 101 and 102, the capacitances of the element can be controlled to desired values.

After the sheets are laminated as above, the laminate is compressed by applying pressure and heat thereto in order for the laminated sheets to come into close contact with each other. Then, the laminate is cut to a proper size. If the laminate is cut along the two-dot chain lines which divide the laminate into the unit elements, each of the unit elements becomes a single chip element. Likewise, if the laminate is cut at a given plurality of the unit elements, each cut laminate with said plurality of the unit elements are manufactured into a single chip element. As shown in FIG. 1, if the laminate is cut so that the four unit elements are arranged on the cut laminate, the single chip element of an array type in which the four unit elements are arranged in parallel with each other may be manufactured.

In practice, the first and second sheets 101 and 102 are manufactured by repeatedly forming a plurality of the first to third conductive patterns on the corresponding sheets at regular intervals. Then, after laminating and compressing the first and second sheets 101 and 102, if the laminate is cut into a desired size, for example, as shown in FIG. 1 (a), such a manufacturing process may be suitable for mass production.

In order to remove organic matter, such as the binder, from the laminate, the laminate is baked out by heating it at about 300° C., and then, sintered at an appropriate sintering temperature (for example, about 1,100° C.) by increasing the temperature.

At this time, the element may be manufactured by forming the external terminals which are connected to the respective conductive patterns and optionally by forming resistive patterns 150 together with metal pads 140 before forming the external terminals.

The metal pads 140 having a predetermined area are formed on the upper surface of the laminate, that is, on the dummy sheet, at positions corresponding to the first and second external terminals 130 and 131. Then, the resistive pattern 150 is formed by printing it on the upper surface of the laminate with resistive paste of RuO₂ and the like to connect the metal pads 140 to each other. Then, an insulated pattern 160 for protecting the resistive patterns 150 may be formed over the resistive patterns 150.

Such a resistive pattern may be formed on a separate sheet. That is, a resistor sheet on which the resistive patterns are armed may be laminated, cut and sintered together with the first and second sheets 101 and 102. The dummy sheet 100 as a protective layer for protecting the patterns on the uppermost surface of the laminated sheets may be further laminated rather than arming the insulated pattern 160. In order to simplify the manufacture, the resistive patterns may be formed without the metal pads 140.

The laminated chip element is completed by forming the external terminals, which are connected to the conductive patterns and the resistive patterns in the laminate, on the outer surfaces of the laminate. With Ag paste applied to a rubber disk (the cylindrical surface of which is formed with grooves corresponding to the number and the positions of the external terminals to be formed), the external terminals are printed by bringing the rubber disk into close contact with the outer surface of the laminate and rotating the rubber disk. Then, the printed laminate is sintered at an appropriate temperature.

After forming the external terminals connected to the conductive patterns and the resistive patterns on the laminate, an insulated protective layer may be armed by printing on the surface of the resistive patterns with epoxy or glass, for example, by the screen printing method.

The insulated pattern 160 and/or the insulated protective layer formed over the resistive patterns can protect the resistive patterns from moisture and the like.

The four pairs of the first conductive pattern 110 and the second conductive pattern 111, which are spaced apart from each other in the direction of both the opposite ends of the first sheet, are formed in parallel with each other on the first sheet 101 of the laminated chip, wherein each pair of the first and second conductive patterns are arranged within a range of each of the unit elements. The third conductive pattern 112 is formed on the second sheet 102 in the transverse direction of both the opposite ends of the first sheet. The resistive patterns 150 are formed on the upper surface of the laminated sheets in the direction of both the opposite ends of the first sheet. In addition, for each unit element, the first and second external terminals 130 and 131, which are connected to the ends of the respective first and second conductive patterns 110 and 111, are input and output terminals (that is, signal electrodes), which are also connected to both the opposite ends of the resistive pattern 150, respectively. The third external terminal 132, which is connected to both the opposite ends of the third conductive pattern 112, is the common terminal (ground electrode). In such a case, the common terminal may be connected to any one end of the third conductive pattern 112.

At this time, a segment divided by the two-dot chain lines functions as a single unit element. There are overlapping portions between the first and second conductive patterns 110 and 111 and the third conductive pattern 112. Since areas of the overlapping portions may be different from each other, a capacitor C1 which has a capacitance of the overlapping portion between the first conductive pattern 110 and the third conductive pattern 112 differs from a capacitor C2 which has a capacitance of the overlapping portion between the second conductive pattern 111 and the third conductive pattern 112. Therefore, the chip element of the present embodiment has a structure that the capacitors C1 and C2 are positioned between the common terminal and the input and output terminals which are connected to both opposite ends of the resistive pattern 150, respectively, as shown in FIG. 3.

It is noted that if a plurality of the first and second sheets 101 and 102 are alternately laminated on each other in the element shown in FIG. 1, the first and second conductive patterns 110 and 11 and the third conductive pattern 112 armed on the intermediate sheets of the laminated first and second sheets 101 and 102 not only overlap with each other but also with the third conductive pattern 112 and the first and second conductive patterns 110 and 111 of the adjacent lower and upper sheets, that is, the outermost sheets. Thus, capacitances are formed at upper and lower portions of the first to third conductive patterns 110 to 111 formed on the intermediate sheets.

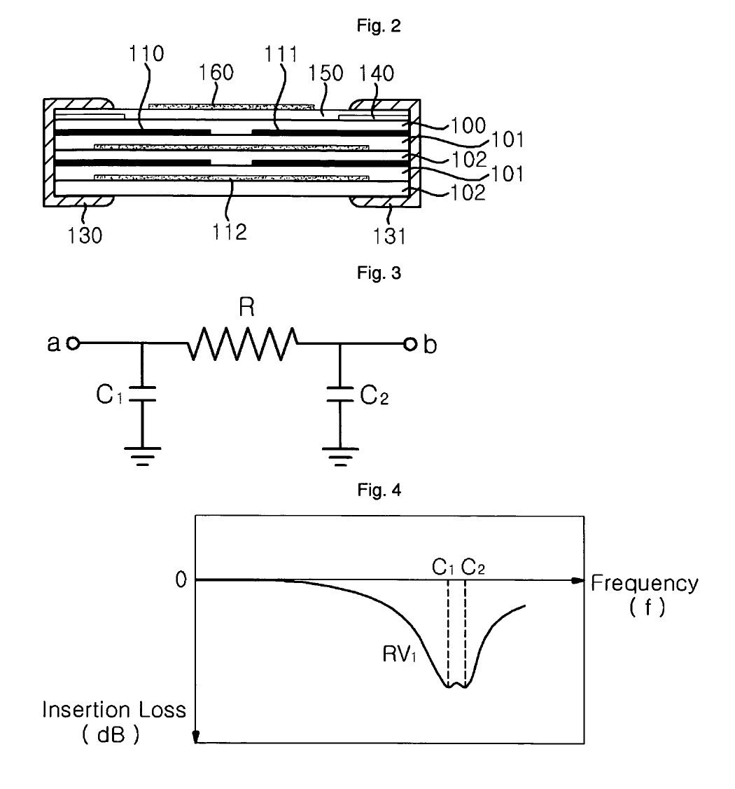

As shown in a sectional view of FIG. 2, the metal pads 140 are formed at both ends of the resistive pattern 150 in the laminated chip element, respectively. Therefore, if the distance between the metal pads 140 is controlled with accuracy, the resistance of the resistive pattern 150 can also be controlled with accuracy. When a plurality of the unit elements are formed in the single chip, the resistances of the respective unit elements may be made uniform.

Since the capacitances of the capacitors positioned at the input and output terminals are different from each other, when the element of the present embodiment is used as a low pass filter, the element nay have two adjacent self-resonant frequencies due to the two capacitances, as shown in FIG. 4. Thus, the frequency range in which high frequency noise can be removed widens. In addition, since the laminated chip element has a series resistor positioned in the middle of the signal line, that is, between the input and output terminals, the series resistor functions to limit the current of the signal line or functions as a resistor for impedance matching, and particularly in a digital circuit, can prevent a ringing phenomenon occurring in a square wave pulse signal.

In the meantime, some of the conductive patterns may be formed of metal material of Ag, Pt, Pd, or the like in order to increase conductivity, whereas some of the conductive patterns may be farmed of resistive material of Ni—Cr, RuO₂, or the like in order to decrease conductivity. Thus, it is possible to easily perform the impedance matching of the circuit.

### Embodiment 2

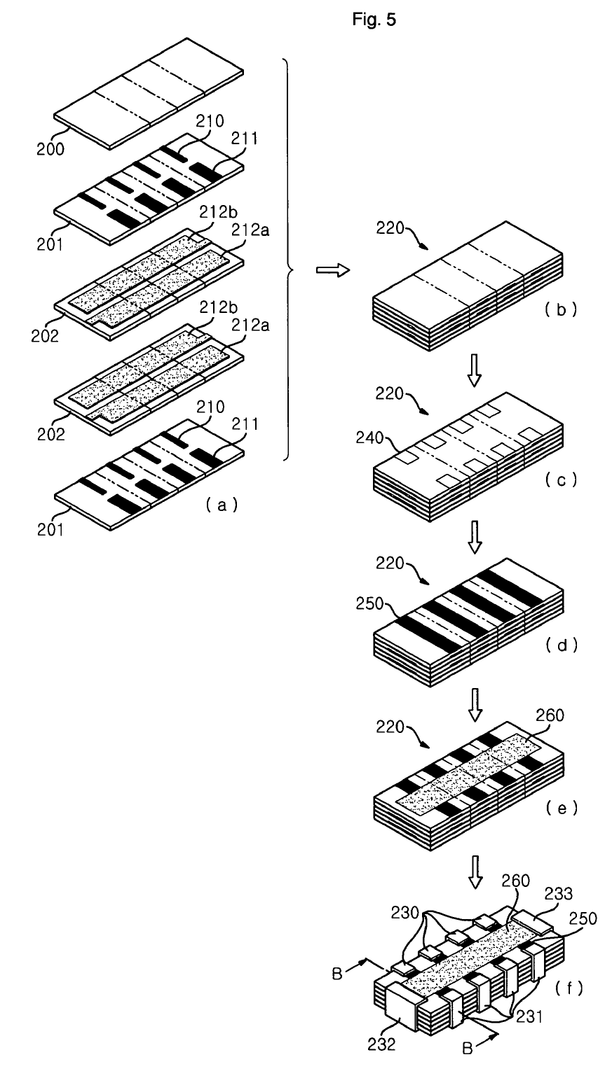

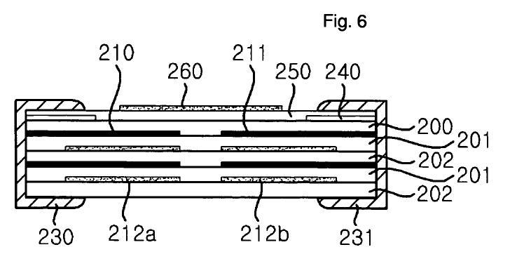

The present embodiment 2 shown in FIGS. 5 and 6 possesses a structure that can change properties of the previous element by modifying the configuration of the conductive pattern, which is connected to the common terminal of the embodiment 1.

FIG. 5 is a view showing a manufacturing process of a laminated chip element according to the present embodiment wherein four unit elements are integrally manufactured into a single chip element.

Green sheets for a desired element are manufactured by the same manner as in the embodiment 1.

Conductive patterns are armed on the green sheets manufactured as above by printing the conductive patterns with conductive paste of Ag, Pt, Pd, or the like, for example, by a screen printing method using screens of internal electrode patterns that are previously designed. That is, a first conductive pattern 210 and a second conductive pattern 211 are formed on a first sheet 201 so that the first and second conductive patterns 210 and 211 are spaced apart from each other in a direction of both opposite ends of the sheet 201. A third conductive pattern 212 consists of a first portion 212a and a second portion 212b which are spaced apart from each other on the second sheet 202 and formed in a transverse direction of both the opposite ends of the first sheet 201. The first and second conductive patterns 210 and 211 may be formed so that widths thereof are different from each other, as shown in FIG. 5 (a).

When a plurality of unit elements, for example, four unit elements are integrally formed in a single chip element, a plurality of pairs of the first and second conductive patterns 210 and 211 are formed in parallel with each other so that each pair of the conductive patterns are arranged within a range of each of the unit elements, into which the chip element is divided by two-dot chain lines. Each of the first and second portions 212a and 212b of the third conductive pattern 212 to be connected to the common terminal (ground electrode) is formed to extend over the unit elements. In addition, an end of the first conductive pattern 210 and an end of the second conductive pattern 211 are exposed to outer surfaces of the laminated element to be connected to first and second external terminals 230 and 231, respectively. Both opposite ends of the first and second portions 212a and 212b are exposed to outer surfaces of the laminated element to be connected to third and fourth external terminals 232 and 233, respectively. The portions of the conductive patterns which are not to be connected to the corresponding external terminals may be not exposed outside of the laminated element.

In the present embodiment shown in FIG. 5 (a), the first and second sheets 201 and 202 are laminated so that two of the second sheets 202 are interposed between two of the first sheets 201, and then a dummy sheet 200 is laminated thereon. Alternatively, in order for the element to have desired capacitance, a plurality of the first and second sheets 201 and 202 may be laminated in various combinations. That is, by controlling the number of laminations of the first and second sheets 201 and 202, the capacitances of the element can be controlled to desired values.

After the sheets are laminated as above, the laminate is compressed, cut to a proper size, baked out, and sintered, as described in the embodiment 1. At this time, the element may be manufactured by forming the external terminals, which are connected to the respective conductive patterns, on the sintered laminate and optionally by forming resistive patterns 250 together with metal pads 240 before forming the external terminals as described in the embodiment 1.

As described in the embodiment 1, the laminated chip element is completed by forming the metal pads 240 and the resistive patterns 250 on the uppermost surface of the sintered laminate and by forming the external terminals, which are connected to the conductive patterns and the resistive patterns in the laminate, on the outer surfaces of the laminate. However, contrary to the embodiment 1, both the opposite ends of the first and second portions 212a and 212b of the third conductive pattern in the present embodiment are connected to the third and the fourth external terminals 232 and 233, respectively.

The first and second conductive patterns and the resistive pattern of the laminated chip element of the present embodiment has the same structure of the embodiment 1, whereas the third and the fourth external terminals 232 and 233 which are connected to both the opposite ends of the first and second portions 212a and 212b of the third conductive pattern, respectively, are the common terminal (ground electrode).

Areas of an overlapping portion between the first conductive pattern 210 and the first portion 212a of the third conductive pattern 212 and an overlapping portion between the second conductive pattern 211 and the second portion 212b of the third conductive pattern 212 are different from each other. Thus, a capacitor C1 which has a capacitance of the overlapping portion between the first conductive pattern 210 and the first portion 212a differs from a capacitor C2 which has a capacitance of the overlapping portion between the second conductive pattern 211 and the second portion 212b. Therefore, the structure of the chip element of the present embodiment is similar to the laminated chip element of the embodiment 1 in that the capacitors of C1 and C2 at both the opposite ends of the resistive pattern 250 are respectively connected to the common terminal. It is, however, possible to realize the frequency properties without mutual interference of C1 and C2 since the con terminal, which is connected to the first portion 212a of the third conductive pattern that cooperates with the first conductive pattern 210, is separated from the common terminal, which is connected to the second portion 212b of the third conductive pattern that cooperates with the second conductive pattern 211.

### Embodiment 3

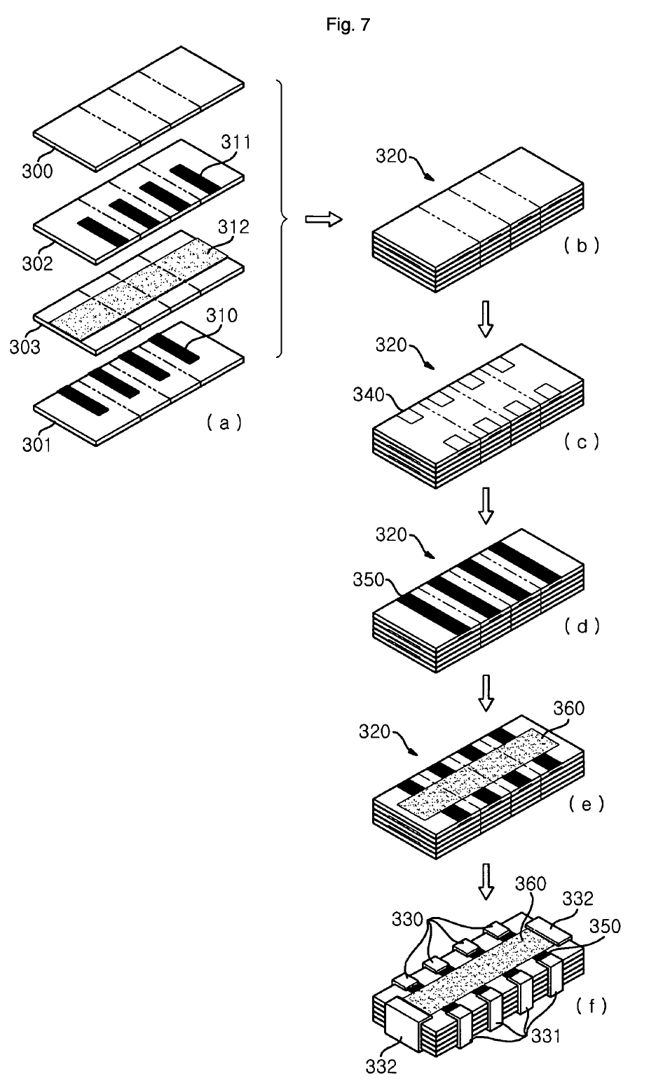

The present embodiment 3 shown in FIG. 7 is similar to the embodiment 1, except that respective first and second conductive patterns are formed on separate sheets.

FIG. 7 is a view showing a manufacturing process of a laminated chip element according to the present embodiment, wherein four unit elements are integrally formed in a single chip element.

Green sheets for a desired element are manufactured by the same manner as in the embodiment 1.

Conductive patterns are formed on the green sheets manufactured as above by printing the conductive patterns with conductive paste of Ag, Pt, Pd, or the like, for example, by a screen printing method using screens of internal electrode patterns that are previously designed. That is, a first conductive pattern 310 is formed on a first sheet 301 in a direction of both opposite ends of the first sheet 301. A second conductive pattern 311 is formed on a second sheet 302 in the same direction of the first conductive pattern 310. A third conductive pattern 312 is formed on the third sheet 303 across the first conductive pattern 310. At this time, the first and second conductive patterns 310 and 311 may be formed so that widths thereof are different from each other.

When a plurality of unit elements, for example, four unit elements are integrally formed in a single chip element, a plurality of pairs of the first and second conductive patterns 310 and 311 are formed in parallel with each other so that each pair of the conductive patterns are arranged within a range of each of the unit elements, into which the chip element is divided by two-dot chain lines. The third conductive pattern 312 to be connected to a common terminal is formed to extend over the unit elements. In addition, both opposite ends of the first and second conductive patterns 310 and 311 are exposed to outer surfaces of the laminated element to be connected to first and second external terminals 330 and 331, respectively, and both opposite ends of the third conductive pattern 312 are exposed to outer surfaces of the laminated element to be connected to a third external terminal 332. Alternatively, any one end of the third conductive pattern 312 may be exposed to an outer surface of the laminated element to be connected to the third external terminal 332. The portions of the conductive patterns which are not to be connected to the corresponding external terminals may be not exposed outside of the laminated element.

The first to third sheets 301 to 303 on which the respective conductive patterns are formed are laminated in order of the first sheet 301, the third sheet 303, and the second sheet 302, and then a dummy sheet 300 is further laminated thereon. Alternatively, in order for the element to have a desired capacitance, a plurality of first to third sheets 301 to 303 may be laminated in various combinations. For example, the first to third sheets 301 to 303 may be laminated in order of the first sheet 301, the third sheet 303, the first sheet 301, the second sheet 302, the third sheet 303, and the second sheet 302. That is, by controlling the number of laminations of the first to third sheets 301 to 303, the capacitances of the element can be controlled to desired values.

After the sheets are laminated as above, the laminate is compressed, cut to a proper size, baked out, and sintered, as describe in the embodiment 1. At this time, the element may be manufactured by forming the external terminals, which are connected to the respective conductive patterns, on the sintered laminate, and optionally by forming resistive patterns 350 together with metal pads 340 before forming the external terminals as described in the embodiment 1.

As described in the embodiment 1, the laminated chip element is completed by arming the metal pads 340 and the resistive patterns 350 on the laminate and by forming the external terminals, which are connected to the conductive patterns and the resistive patterns in the laminate, on the outer surfaces of the laminate.

The four pairs of the first and second conductive patterns 310 and 311 are formed in parallel with each other on the first and second sheets 301 and 302 of the laminated chip element manufactured as above, respectively, wherein each pair of the first and second conductive patterns 310 and 311 are formed within a range of each of the unit elements to be extended in the direction toward both the opposite ends of the sheets. The third conductive pattern 312 is formed on the third sheet 303 in a transverse direction of both the opposite ends of the sheet. The resistive patterns 350 are formed on the laminated sheets in the direction of both the opposite ends of the sheet. In addition, for each unit element, the first and second external terminals 330 and 331 connected to one ends of the first and second conductive patterns 310 and 311, are input and output terminals (that is, signal electrodes), which are also connected to both the opposite ends of the resistive pattern 350, respectively. The third external terminal 332, which is connected to both the opposite ends of the third conductive pattern 312, is the common terminal (ground electrode). In such a case, the common terminal may be connected to any one end of the third conductive pattern 312.

Areas of an overlapping portion between the first conductive pattern 310 and the third conductive pattern 312 and an overlapping portion between the second conductive pattern 311 and the third conductive pattern 312 may be different from each other. Thus, a capacitor C1 which has a capacitance of the overlapping portion between the first conductive pattern 310 and the third conductive pattern 312 is also different from a capacitor C2 which has a capacitance of the overlapping portion between the second conductive pattern 311 and the third conductive pattern 312. Accordingly, the chip element of the present embodiment has a structure that the capacitors C1 and C2 at both the opposite ends of the resistive pattern 30 are connected to the common terminal, respectively.

Although the chip element of the present embodiment has the similar properties of the laminated chip element of the embodiment 1, since the first conductive pattern 310 and the second conductive pattern 311 are formed on the different sheets, respectively, the overlapping portions of the conductive patterns, which may define the capacitance, can be freely designed.

### Embodiment 4

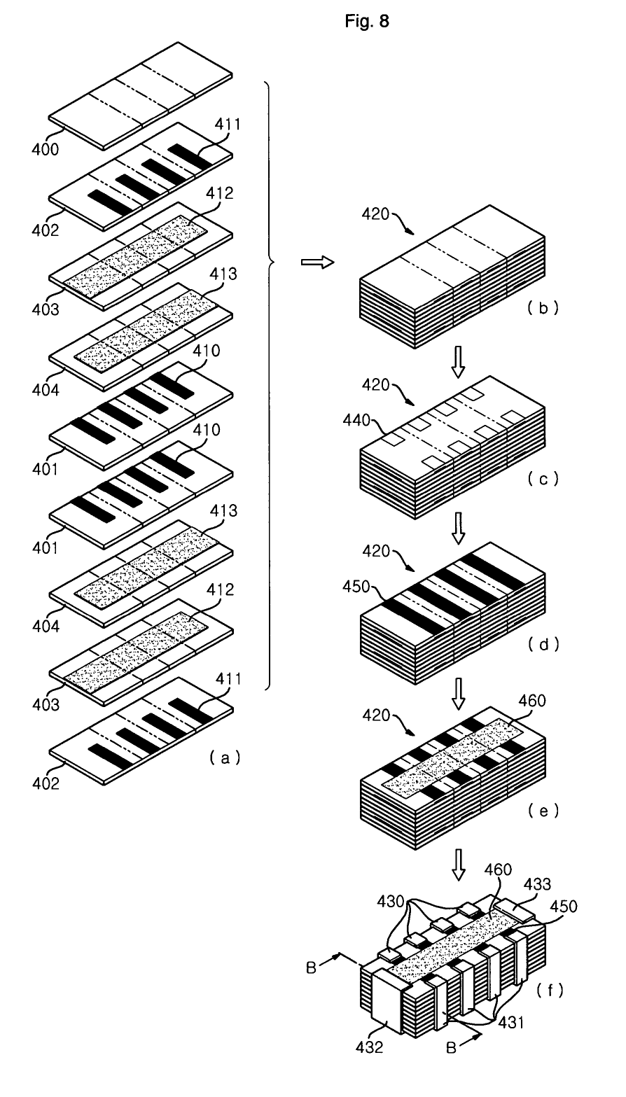

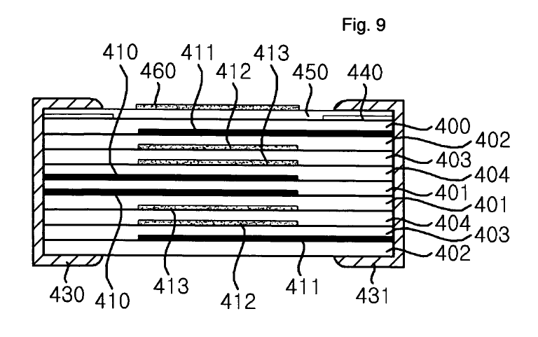

The present embodiment 4 shown in FIGS. 8 and 9 is similar to the embodiment 3, except that conductive patterns connected to a common terminal, which cooperate with first and second conductive patterns 410 and 411, respectively, are formed on the separate sheets.

FIG. 8 is a view showing a manufacturing process of a laminated chip element according to the present embodiment, wherein four unit elements are integrally formed in a single chip element.

Green sheets for a desired element are manufactured by the same manner as in the embodiment 1.

Conductive patterns are formed on the green sheets manufactured as above by printing the conductive patterns with conductive paste of Ag, Pt, Pd, or the like, for example, by a screen printing method using screens of internal electrode patterns that are previously designed. That is, the first conductive pattern 410 is formed on a first sheet 401 in a direction of both opposite ends of the sheet. The second conductive pattern 411 is formed on a second sheet 402 in the same direction of the first conductive pattern 410. A third conductive pattern 412 is formed on the third sheet 403 across the first conductive pattern 410. In addition, a fourth conductive pattern 413 is formed on the fourth sheet 404 in the same direction of the third conductive pattern 412. At this time, the first and second conductive patterns 410 and 411 may be formed so that widths thereof are different from each other.

When a plurality of unit elements, for example, four unit elements are integrally formed in a single chip element, a plurality of pairs of the first and second conductive patterns 410 and 411 are formed in parallel with each other so that each pair of the conductive patterns are arranged within a range of each of the unit elements, into which the chip element is divided by two-dot chain lines. Each of the third and fourth conductive patterns 412 and 413 to be connected to the common terminal (ground electrode) is formed to extend over the unit elements. In addition, both opposite ends of the first and second conductive patterns 410 and 411 are exposed to outer surfaces of the laminated element to be connected to first and second external terminals 430 and 431, respectively. Both opposite ends of the third and fourth patterns 412 and 413 are exposed to outer surfaces of the laminated element to be connected to third and fourth external terminals 432 to 433, respectively. The portions of the conductive patterns which are not to be connected to the corresponding external terminals may be not exposed outside of the laminated element.

The first to fourth sheets 401 to 404 on which the respective conductive patterns are formed are laminated in order of the second sheet 402, the third sheet 403, the fourth sheet 404, the first sheet 401, the first sheet 401, the fourth sheet 404, the third sheet 403, and the second sheet 402, and then, a dummy sheet 400 is further laminated thereon. Alternatively, in order for the element to have a desired capacitance, a plurality of the first to fourth sheets 401 to 404 may be laminated in various combinations. For example, the first to fourth sheets 401 to 404 may be laminated so that the third and fourth sheets 403 and 404 are interposed between the first sheet 401 and the second sheet 402. That is, by controlling the number of laminations of the sheets, the capacitances of the element can be controlled to desired values.

After the sheets are laminated as above, the laminate is compressed, cut to a proper size, baked out, and sintered, as describe in the embodiment 1. At this time, the element may be manufactured by forming the external terminals, which are connected to the respective conductive patterns, on the sintered laminate, and optionally by forming resistive patterns 450 together with metal pads 440 before forming the external terminals as described in the embodiment 1.

As described in the embodiment 1, the laminated chip element is completed by forming the metal pads 440 and the resistive patterns 450 on the sintered laminate and by firming the external terminals, which are connected to the conductive patterns and the resistive patterns in the laminate, on the outer surfaces of the laminate. However, contrary to the embodiments 1 and 3, in the present embodiment, both the opposite ends of the third and fourth conductive patterns 412 and 413 are connected to the third and the fourth external terminals 432 and 433, respectively.

The four pairs of the first and second conductive patterns 410 and 411 are formed in parallel with each other on the first and second sheets 401 and 402 of the laminated chip element manufactured as above, respectively, wherein each pair of the first and second conductive patterns 410 and 411 are formed within a range of each of the unit elements to be extended in the direction toward both the opposite ends of the sheet. The third and fourth conductive patterns 412 and 413 are formed on the third and fourth sheets 403 and 404 in a transverse direction of the first or second conductive pattern, respectively. The resistive patterns 450 are formed on the laminated sheets in the same direction of the first or second conductive pattern. In addition, for each unit element, the first and second external terminals 430 and 431 connected to one ends of the first and second conductive patterns 410 and 411, are input and output terminals (that is, signal electrodes), which are also connected to both the opposite ends of the resistive pattern 450, respectively. The third and fourth external terminals 432 and 433, which are connected to both the opposite ends of the third and fourth conductive patterns 412 and 413, respectively, are the common terminal (ground electrode).

A segment divided by the two-dot chain lines functions as a single unit element. First, as seen from the laminate of the first to fourth sheets 401 to 404 which are laminated as shown in FIG. 8, there are overlapping portions between the first and third conductive patterns 410 and 412 and between the second and fourth conductive patterns 411 and 413. At this time, since areas of the overlapping portions may be different from each other, a capacitor C1 which has a capacitance of the overlapping portion between the first conductive pattern 410 and the third conductive pattern 412 is also different from a capacitor C2 which has a capacitance of the overlapping portion between the second conductive pattern 411 and the fourth conductive pattern 413. Therefore, the chip element of the present embodiment has a structure that the capacitors C1 and C2 at both the opposite ends of the resistive pattern 150 are connected to the common terminal, respectively. Even if the third sheet 402 and the fourth sheet 403 are replaced with each other, the same result is obtained.

The laminated chip element manufactured as above has similar properties of the laminated chip element of the embodiment 3, except that the common terminal connected to the third conductive pattern 412 that cooperates with the first conductive pattern 410 is separated from the common terminal connected to the fourth conductive pattern 413 that cooperates with the second conductive pattern 411, since the third conductive pattern 412 and the fourth conductive pattern 413 are formed on the different sheets, respectively. If the conductive patterns connected to the common terminal are separated from each other, it is possible to realize the frequency properties without mutual interference of the capacitors C1 and C2. In addition, if the directions of currents flowing in the respective capacitors are fixed constantly, an equivalent series inductance may be increased.

In addition, the metal pads 440 may be formed at both ends of the resistive pattern 450 in the laminated chip element, respectively, as described in the embodiment 1. Therefore, if a distance between the metal pads 440 is controlled with accuracy, the resistance of the resistive pattern 450 can also be controlled with accuracy. Furthermore, since the capacitances of the capacitors positioned at the input and output terminals are different from each other, when the element is used as a low pass filter, the element may have two adjacent self-resonant frequencies due to the two capacitances. Thus, frequency range in which high frequency noise can be removed widens.

### Embodiment 5

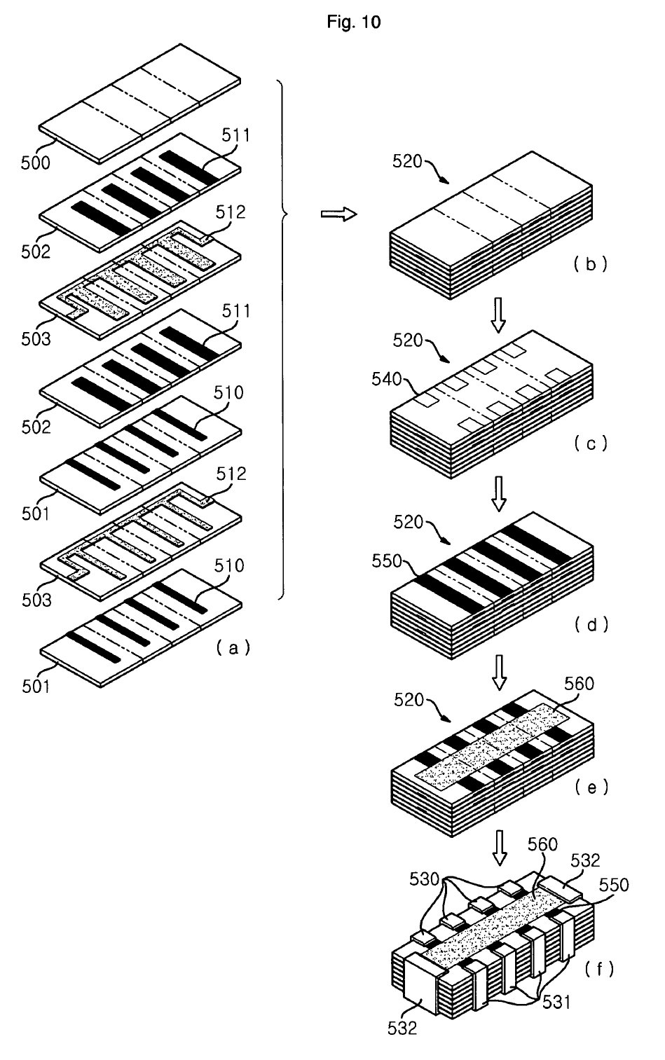

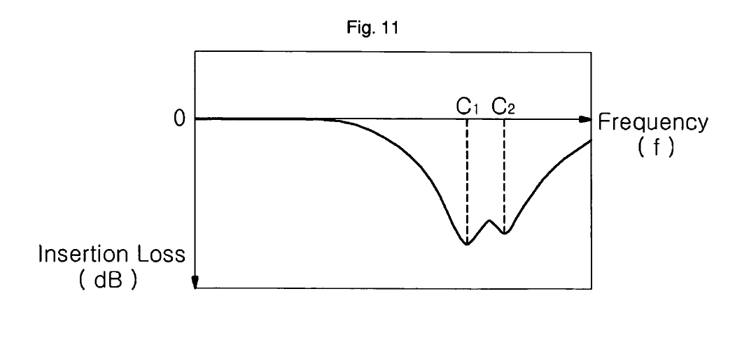

The present embodiment 5 shown in FIGS. 10 and 11 is similar to the embodiment 4, except that conductive pattern to be connected to a common terminal is modified.

FIG. 10 is a view showing a manufacturing process of a laminated chip element according to the present embodiment, wherein four unit elements are integrally formed in a single chip element.

Green sheets for a desired element are manufactured by the same manner as in the embodiment 1.

Conductive patterns are formed on the green sheets manufactured as above by printing the conductive patterns with conductive paste of Ag, Pt, Pd, or the like, for example, by a screen printing method using screens of internal electrode patterns that are previously designed. That is, the first conductive pattern 510 is formed on a first sheet 501 in a direction of both opposite ends of the sheet 501. The second conductive pattern 511 is armed on a second sheet 502 in the same direction of the first conductive pattern 510. A third conductive pattern 512 is formed on a third sheet 503 in the same direction of the first conductive pattern 510. At this time, the first and second conductive patterns 510 and 511 may be formed so that widths thereof are different from each other.

When a plurality of unit elements, for example, four unit elements are integrally formed in a single chip element, a plurality of sets of the first to third conductive patterns 510 to 512 are formed in parallel with each other so that each set of the conductive patterns are arranged within a range of each of the unit elements, into which the chip element is divided by two-dot chain lines. In addition, for each unit element, both opposite ends of the first and second conductive patterns 510 and 511 are exposed to outer surfaces of the laminated element to be connected to first and second external terminals 530 and 531, respectively. One ends of the third conductive patterns 512 are connected to each other. Also, one ends of both outermost ones of the third conductive patterns 512 are extended to edges of the third sheet 503 so that the one ends are exposed to outer surfaces of the laminated element to be connected to a third external terminal 532. Alternatively, any one end of both the outermost third conductive patterns 512 is extended to an edge of the third sheet 503 so that the one end is exposed to an outer surface of the laminated element to be connected to the third external terminal 532. The portions of the conductive patterns which are not to be connected to the corresponding external terminals may be not exposed outside of the laminated element.

The first to third sheets 501 to 503 on which the respective conductive patterns are formed are laminated in order of the first sheet 501, the third sheet 503, the first sheet 501, the second sheet 502, the third sheet 503, and the second sheet X, and then, a dummy sheet 500 is further laminated thereon, as shown in FIG. 10. That is, a first laminate consisting of two of the first sheets 501 and one of the third sheets 513 interposed between the two first sheets 501 is laminated on a second laminate consisting of two of the second sheets 502 and one of the third sheets 503 interposed between the two second sheets 502. Particularly, the conductive patterns formed on the sheets in the first laminate may have smaller area than the conductive patterns formed on the sheets in the second laminate. Alternatively, in order for the element to have a desired capacitance, a plurality of the first to third sheets 501 to 503 may also be laminated in various combinations. For example, the first to third sheets 501 to 503 may be laminated so that the third sheet 503 is interposed between the first sheet 501 and the second sheet 502. That is, by controlling the number of laminations of the sheets, a capacitance of the element can be controlled to desired value.

After the sheets are laminated as above, the laminate is compressed, cut to a proper size, baked out, and sintered, as describe in the embodiment 1. At this time, the element may be manufactured by forming the external terminals, which are connected to the respective conductive patterns, on the sintered laminate, and optionally by arming resistive patterns 550 together with metal pads 540 before forming the external terminals as described in the embodiment 1.

That is, as described in the embodiment 1, the laminated chip element is completed by firming the metal pads 540 and the resistive patterns 550 on the sintered laminate and by forming the external terminals, which are connected to the conductive patterns and the resistive patterns in the laminate, on the outer surfaces of the laminate.

The four pairs of the first and second conductive patterns 510 and 511 are formed in parallel with each other on the first and second sheets 501 and 50 of the laminated chip element manufactured as above, respectively, wherein each pair of the first and second conductive patterns 510 and 511 are formed within a range of each of the unit elements to be extended in the direction of both the opposite ends of the sheets. The four third conductive patterns 512 are formed in parallel with each other on the third sheets 503 in the same direction of the first or second conductive pattern 510 or 511. The resistive patterns 550 are formed on the laminated sheets in the same direction of the first or second conductive pattern. At this time, each pair of the third conductive patterns 512 and resistive patterns 550 are also are formed within a range of each of the unit elements. In addition, for each unit element, the first and second external terminals 530 and 531 connected to one ends of the first and second conductive patterns 510 and 511, are input and output terminals (that is, signal electrodes), which are also connected to both the opposite ends of the resistive pattern 550, respectively. The third external terminal 532, which is connected to one ends of both the outermost third conductive patterns 512, respectively, is the common terminal (ground electrode). The common terminal may be connected to any one end of both the outermost third conductive patterns 512.

The present embodiment is similar to the previous embodiments in that capacitors, the capacitances of which are formed in the overlapping portions, are positioned between the common terminal and the input and output terminals connected to both the opposite ends of the resistive pattern. However, as shown in FIG. 10, the first conductive patterns 510 in the first laminate, which have smaller overlapping portion between the first conductive patterns and the third conductive pattern, are connected to the input terminal, while the second conductive patterns 511 in the second laminate, which have larger overlapping portion between the second conductive patterns and the third conductive pattern, are connected to the output terminal. Thus, while a capacitor C1 at the input terminal is larger in capacitance and equivalent inductance, a capacitor C2 at the output terminal is smaller in capacitance and equivalent inductance. Accordingly, as shown in FIG. 11, since the element may have two adjacent self-resonant frequencies due to the two capacitances, frequency range in which high frequency noise can be removed widens.

### Embodiment 6

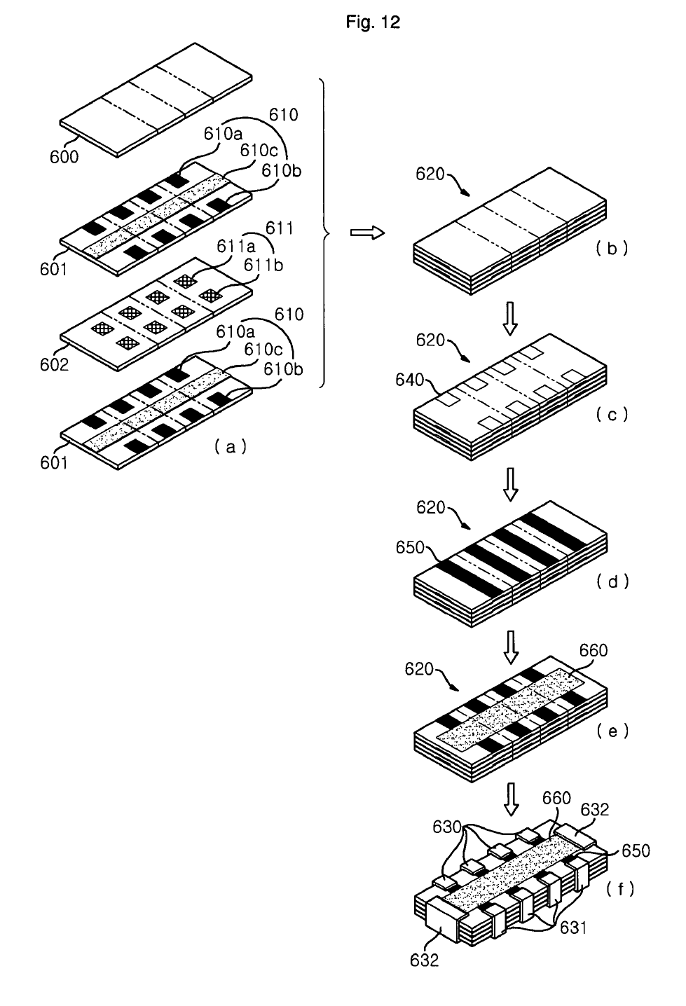

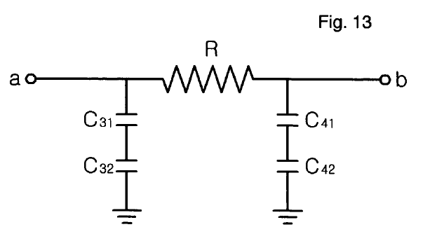

The present embodiment 6 shown in FIGS. 12 and 13 has a structure that capacitances of an element can be varied by forming respective conductive patterns connected to input, output, and common terminals on the same sheet.

FIG. 12 is a view showing a manufacturing process of a laminated chip element according to the present embodiment, wherein four unit elements are integrally formed in a single chip element.

Green sheets for a desired element are manufactured by the same manner as in the embodiment 1.

Conductive patterns are formed on the green sheets manufactured as above by printing the conductive patterns with conductive paste of Ag, Pt, Pd, or the like, for example, by a screen printing method using screens of internal electrode patterns that are previously designed. That is, a first conductive pattern 610 consisting of first to third portions 610a to 610c is formed on the first sheet 601 so that the first and second portions 610a and 610b are spaced apart from each other in a direction of both opposite ends of the sheet 601, and the third portion 610c is spaced apart from the first and second portions 610a and 610b therebetween and formed in a transverse direction of both the opposite ends. At this time, one ends of the first and second portions 610a and 610b and both opposite ends of the third portion 610c are formed to be connected to external terminals. The first and second conductive patterns 610 and 611 may be formed so that widths thereof are different from each other.

In addition, a second conductive pattern 611 consisting of fourth and fifth portions 611a and 611b, which are insulated from the external terminals, is armed on a second sheet 602 so that the fourth portion 611a partially overlaps with the first and third portions 610a and 610c of the first conductive pattern 610 of the first sheet 601 and the fifth portion 611b partially overlaps with the second and third portions 610b and 610c of the first conductive pattern 610 of the first sheet 601.

When a plurality of unit elements, for example, four unit elements are integrally armed in a single chip element, a plurality of sets of the first and second portions 610a and 610b of the first conductive pattern 610 and the fourth and fifth portions 611a and 611b of the second conductive pattern 611 are formed in parallel with each other so that each set thereof is arranged within a range of each of the unit elements, into which the chip element are divided by two-dot chain lines. The third portion 610c of the first conductive pattern 610 to be connected to a common terminal is formed to extend over the unit elements.

In the present embodiment shown in FIG. 12, the first and second sheets 601 and 602 are laminated in order of the first sheet 601, the second sheet 602, and the first sheet 601, and then, a dummy sheet 600 is further laminated thereon. However, in order for the element to have a desired capacitance, a desired number of the first and second sheets 601 and 602 may be alternately laminated on each other, or may be laminated in various combinations. Thus, by controlling the number of laminations of the first and second sheets 601 and 602, the capacitances of the element can be controlled to desired values.

After the sheets are laminated as above, the laminate is compressed, cut to a proper size, baked out, and sintered, as describe in the embodiment 1. At this time, the element may be manufactured by forming the external terminals, which are connected to the respective conductive patterns, on the sintered laminate, and optionally by forming resistive patterns 650 together with metal pads 640 before forming the external terminals as described in the embodiment 1.

As described in the embodiment 1, the laminated chip element is completed by forming the metal pads 640 and the resistive patterns 650 on the laminate and by forming the external terminals, which are connected to the conductive patterns and the resistive patterns in the laminate, on outer surfaces of the laminate.

The laminated unit element, in which the first sheet 601 and the second sheet 602 are laminated, will be explained. The first conductive pattern 610 is formed so that the first and second portions 610a and 610b are spaced apart from each other in the direction of both opposite ends of the sheet, and the third portion 610c is spaced apart from the first and second portions 610a and 610b therebetween and formed in the transverse direction of both the opposite ends. For each unit element, the one ends of the first and second portions 610a and 610b are connected to first and second external terminals 630 and 631 which are the input and output terminals, and are also connected to both opposite ends of the resistive pattern 650, respectively. Both the opposite ends of the third portion 610c are connected to a third external terminal 632 which is the common electrode. In such a case, the cannon terminal may be connected to any one end of the third portion 610c. In addition, the second sheet 602 is formed with the second conductive pattern 611 consisting of the fourth and fifth portions 611a and 611b, which are insulated from the external terminals, so that the second sheet 602 may be referred to as a floating layer. In the second conductive pattern 611 on the second sheet 602, the fourth portion 611a partially overlaps with the first and third portions 610a and 610c, while the fifth portion 611b partially overlaps with the second and third portions 610b and 610c.

The first and third portions 610a and 610c partially overlap with the fourth portion 611a, causing two overlapping portions therebetween, while the second and third portions 610b and 610c partially overlap with the fifth portion 611b, causing two overlapping portions therebetween. Since capacitances are formed at the overlapping portions proportional to areas of the overlapping portions, capacitors C31 and C32 are formed in series between the first portion 610a connected to the input terminal a (see FIG. 13) and the third portion 610c connected to the common terminal, while capacitors C41 and C42 are formed in series between the second portion 610b connected to the output terminal b (see FIG. 13) and the third portion 610c connected to the common terminal. In addition, a resistor formed by the resistive pattern 650 is connected between the input and output terminals a and b. An equivalent circuit diagram of such a structure is shown in FIG. 13.

The laminated chip element manufactured as above comprises a plurality of the capacitors at the input and output terminals, as shown in FIG. 13. Such a structure may be preferably designed when a plurality of the capacitors are necessary to be installed at the input and output terminals. As the foregoing, if the capacitors are connected to each other in series at the respective input and output terminals by laminating the first and second sheets 601 and 602, the equivalent capacitance may be reduced. Therefore, by increasing the number of the laminations of the sheets for obtaining the same capacitance, an equivalent series resistance may lower and frequency properties, such as the insertion loss, may be improved.

In the meantime, although there is a resistor sheet on which the resistive pattern is formed in the embodiments 1 to 6, in order to control the resistance, a plurality of the resistor sheets may be laminated, and the area of the resistive pattern may be also varied.

### Embodiment 7

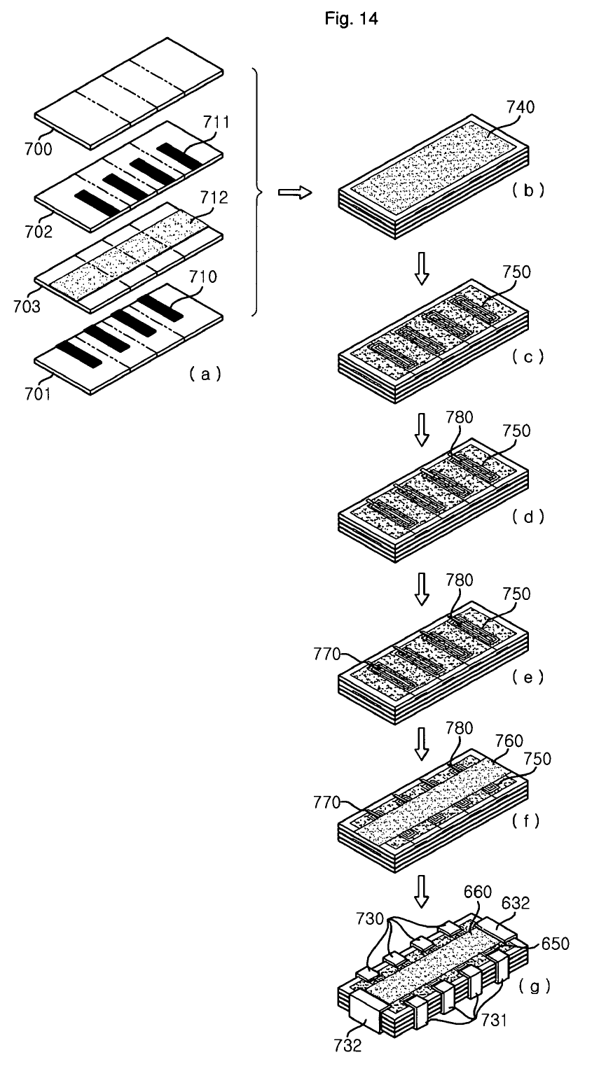

The present embodiment 7 shown in FIGS. 14 to 18 is similar to the embodiment 3, except that an inductive pattern instead of the resistive pattern is formed on a dummy sheet.

FIG. 14 is a view showing a manufacturing process of a laminated chip element according to the present embodiment, wherein four unit elements are integrally formed in a single chip element.

Green sheets for a desired element are manufactured by the same manner as in the embodiment 1.

Conductive patterns are formed on the green sheets manufactured as above by printing the conductive patterns with conductive paste of Ag, Pt, Pd, or the like, for example, by a screen printing method using screens of internal electrode patterns that are previously designed. That is, a first conductive pattern 710 is formed on a first sheet 701 in a direction of both opposite ends of the first sheet 701. A second conductive pattern 711 is formed on a second sheet 702 in the same direction of the first conductive pattern 710. A third conductive pattern 712 is formed on the third sheet 703 across the first conductive pattern 710. At this time, the first and second conductive patterns 710 and 711 may be formed so that widths thereof are different from each other.

When a plurality of unit elements, for example, four unit elements are integrally formed in a single chip element, a plurality of pairs of the first and second conductive patterns 710 and 711 are formed in parallel with each other so that each pair of the conductive patterns are arranged within a range of each of the unit elements, into which the chip element is divided by two-dot chain lines. The third conductive pattern 712 to be connected to a common terminal is armed to extend over the unit elements. In addition, both opposite ends of the first and second conductive patterns 710 and 711 are exposed to outer surfaces of the laminated element to be connected to first and second external terminals 730 and 731, respectively. Both opposite ends of the third conductive pattern 712 are exposed to outer surfaces of the laminated element to be connected to a third external terminal 732. Alternatively, any one end of the third conductive pattern 712 may be exposed to an outer surface of the laminated element to be connected to the third external terminal 732. The portions of the conductive patterns which are not to be connected to the corresponding external terminals nay be not exposed outside of the laminated element.

The first to third sheets 701 to 703 on which the respective conductive patterns are formed are laminated in order of the first sheet 701, the third sheet 703, and the second sheet 702, and then a dummy sheet 700 is further laminated thereon. Alternatively, in order for the element to have a desired capacitance, a plurality of the first to third sheets 701 to 703 may be laminated in various combinations.

After the sheets are laminated as above, the laminate is compressed, cut to a proper size, baked out, and sintered, as describe in the embodiment 1.

Then, after printing a ferrite pattern 740 on the dummy sheet 700 of an upper portion of the sintered laminate, an inductive pattern 750 is formed thereon, for example, in a spiral shape from any one end of both the opposite ends of the sheet, as shown in FIG. 14 (c). In order to extend the center end of the spiral inductive pattern 750 to the other opposite end of the sheet, an insulated bridge 780 is formed from near the center end of the spiral inductive pattern 750 to the other opposite end of the sheet across the spiral inductive pattern 750, as shown in FIG. 14 (d). Then, a bridge pattern 770 is formed on the insulated bridge 780 so that the center end of the spiral inductive pattern 750 is connected to the other opposite end of the sheet, as shown in FIG. 14 (e). A plane view of such a spiral inductive pattern structure is shown in FIG. 15. At this time, in order to secure the connection between the inductive pattern 750 and the external terminals, metal pads (not shown) may be formed at positions corresponding to both the ends of the inductive pattern 750 to be connected to the first and second external terminals before forming the inductive pattern 750.

The spiral inductive pattern may be farmed on a separate sheet. That is, after manufacturing an inductor sheet by forming the inductive pattern on a sheet, for example, which may be molded of ferrite, the inductor sheet may be laminated together with the first to third sheets, and then, the laminate nay be compressed, cut, and then sintered at once. An insulated pattern 760 for protecting the inductive patterns 750 may be formed on the upper surface of the laminate, or the dummy sheet may be further laminated thereon.

After forming the insulated pattern 760 for protecting the inductive patterns 750, as shown in FIG. 14 (f), the laminated chip element is completed by firming the first to third external terminals 730 to 732. At this time, both ends of the inductive pattern 750 are connected to the first and second external terminals 730 and 731, respectively.

In addition, after forming the external terminals connected to the conductive patterns and the inductive pattern on the laminate, an insulated protective layer may be formed by printing it on the surface of the inductive pattern with epoxy or glass, for example, by the screen printing method.

The four pairs of the first and second conductive patterns 710 and 711 are formed in parallel with each other on the first and second sheets 701 and 702 of the laminated chip element manufactured as above, respectively, wherein each pair of the first and second conductive patterns 710 and 711 are formed within a range of each of the unit elements to be extended in the direction toward both the opposite ends of the sheet 701 and 702. The third conductive pattern 712 is formed on the third sheet 703 in a transverse direction of both the opposite ends of the sheet. The spiral inductive patterns 750 are formed on the laminated sheets at positions corresponding to the respective unit elements. In addition, for each unit element, the first and second external terminals 730 and 731 connected to one ends of the first and second conductive patterns 710 and 711, are input and output terminals (that is, signal electrodes), which are also connected to both the opposite ends of the inductive pattern 750, respectively. The third external terminal 732, which is connected to both the opposite ends of the third conductive pattern 712, is the common terminal (ground electrode). In such a case, the common terminal may be connected to any one end of the third conductive pattern 712.

There are overlapping portions between the first conductive pattern 710 and the third conductive pattern 712 and between the second conductive pattern 711 and the third conductive pattern 712. Since areas of the overlapping portions are different from each other, a capacitor C1 which has a capacitance of the overlapping portion between the first conductive pattern 710 and the third conductive pattern 712 is also different from a capacitor C2 which has a capacitance of the overlapping portion between the second conductive pattern 711 and the third conductive pattern 712. Therefore, the chip element of the present embodiment has a structure that the respective capacitors C1 and C2 at both ends of the inductor are connected to the common terminal. FIG. 16 shows an equivalent circuit diagram thereof.

Although the inductive pattern is formed in the spiral shape in the element shown in FIGS. 14 and 15 of the present embodiment, the shape of the inductive pattern may be diversely modified. For example, as shown in FIG. 17, after printing the ferrite pattern 740 on the dummy sheet 700 of an upper portion of the sintered laminate, a straight conductive pattern of metal paste, as an inductive pattern, may be formed thereon.

In addition, when a plurality of unit elements are integrally formed in a single chip element, all of the inductive patterns, each of which corresponds to each unit element, are formed on the same surface of the laminate in the elements shown in FIGS. 14, 15 and 17. However, if the chip element is compact, it is very difficult to form the complicated spiral inductive patterns and there is a limitation to a printing resolution when printing the inductive patterns on the laminate. In order to solve the problems, the inductive patterns may be formed on both lower and upper surfaces of the laminated sheet, as shown in FIG. 18 which is top and bottom perspective views of the element. That is, for example, as shown in FIG. 18, when the four unit elements are formed in a single chip element, the spiral inductive patterns of the first and third unit elements are formed on the upper surface of the laminated sheet, and the spiral inductive patterns of the second and fourth unit elements are formed on the lower surface of the laminated sheet. Thus, since an area for forming each of the spiral inductive patterns is increased, it is easy to form the inductive patterns.

Although the element, which has the same conductive patterns as in the element of the embodiment 3 except that the inductive pattern instead of the resistive pattern is formed on the dummy sheet, has been described in the present embodiment, the inductive pattern may be formed instead of the resistive pattern on the laminated sheets of the embodiments 1 to 6 by the same manner as in the present embodiment.

The laminated chip element makes it possible to manufacture a pi-shaped (π-shaped) filter including the inductor and capacitor by forming the inductive pattern and the overlapped conductive patterns. Also, since the capacitances of the capacitors positioned at the input and output terminals may be different from each other, when the element is used as a low pass filter, the chip element combined with the inductor of the present embodiment may have two adjacent self-resonant frequencies due to the two capacitances. Thus, frequency range in which high frequency noise can be removed widens.

In the meantime, the inductive pattern of the chip element combined with the inductor of the present embodiment may be formed of metal material, such as Ag, Pt, Pd, or resistive material, such as Ni—Cr, RuO₂.

### Embodiment 8

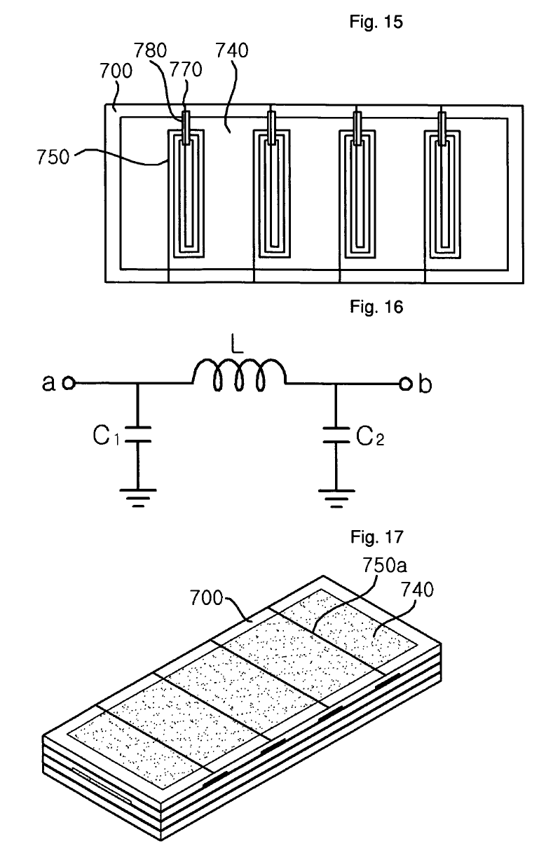

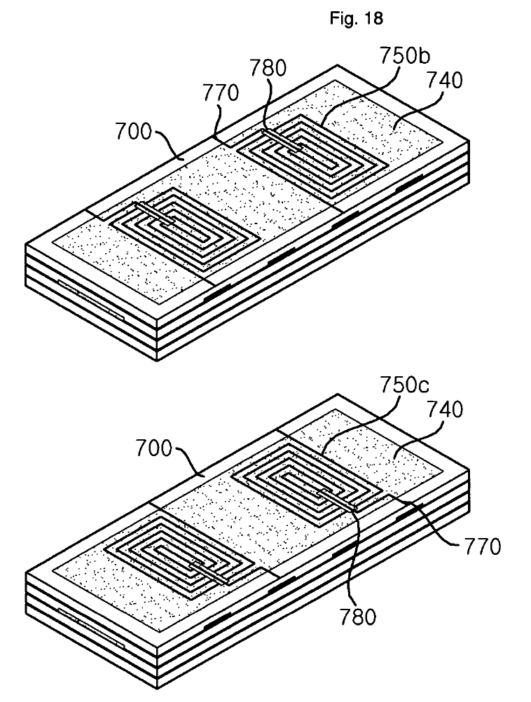

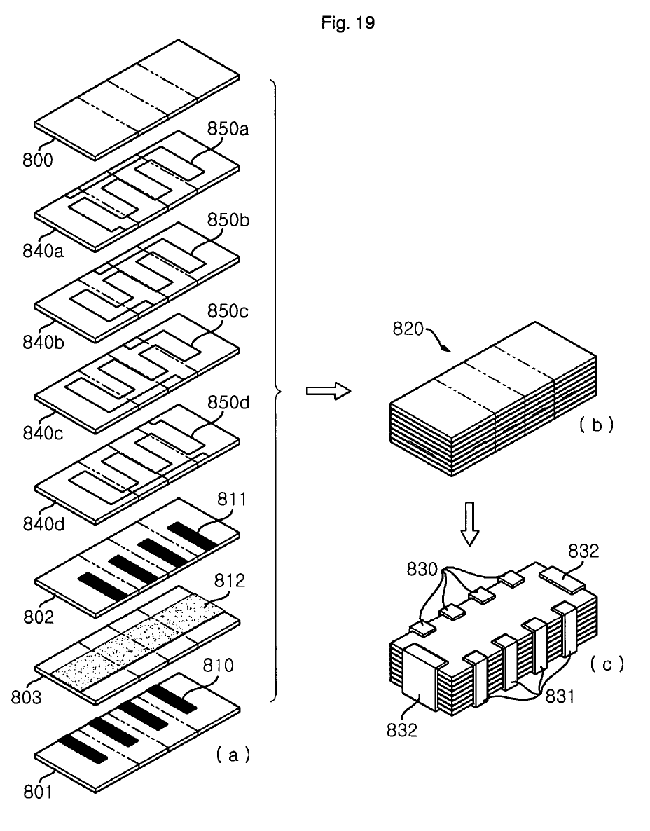

FIG. 19 is a view showing a manufacturing process of a laminated chip element combined with inductors according to the present embodiment 8, wherein four unit elements are integrally formed in a single chip element with an inductive pattern for each unit element formed on each sheet.

The present embodiment is preferable when a plurality of the unit elements are integrally formed in a single chip element. First to third sheets 801 to 803 on which conductive patterns for four unit elements are formed are manufactured by the same manner as in the embodiment 7.

Inductor sheets, which are laminated on the laminate of the first to third sheets 801 to 803, are manufactured by forming inductive patterns on sheets which may be molded of ferrite, as described in the embodiment 7. A meander-shaped inductive pattern 850a for a first one of the unit elements, into which the single chip element is divided by two-dot chain lines, is formed on a first inductor sheet 840a beyond the boundaries of the unit elements. However, both opposite ends of the inductive pattern 850a are positioned at both opposite ends of first unit element. By the same manner as above, meander-shaped inductive patterns 850b to 850d for the second to fourth unit elements are armed on second to fourth inductor sheets 840b to 840d. At this time, in order to secure the connection between the inductive pattern 750 and the external terminals, metal pads (not shown) may be formed at positions corresponding to both the ends of each of the inductive patterns 850a to 850d to be connected to the first and second external terminals before forming the inductive patterns 850a to 850d.

As shown in FIG. 19 (a), in the laminated chip element according to the present embodiment, after laminating the first to third sheets 801 to 803, the first to fourth inductor sheets 840a to 840d are laminated on the laminate of the first to third sheets 801 to 803, and then, a dummy sheet 800 is laminated thereon.

After the sheets are laminated as above, the laminated chip element is completed by compressing, cutting, baking out, and sintering the laminate, and forming external terminals, by the same manner as in the previous embodiments.

The laminated chip element combined with the inductor has the same conductive patterns as in the element of the embodiment 7 and the meander-shaped inductive patterns 850a to 850d connected to respective input and output terminals corresponding to the respective unit elements. That is, the laminated chip element of the present embodiment is similar to that of the embodiment 7, except that the four inductor sheets 840a to 840d, on which the inductive patterns 850a to 850d for the unit elements are formed, respectively, are laminated on each other when the four unit elements are formed into a single chip element, as shown in FIG. 19. Thus, since each inductive pattern is formed on a sheet, the laminated chip element of the present embodiment can make its inductance increase. It is easy to form the inductive patterns with a desired inductance on the inductor sheet with a larger area.

Although the present embodiment is explained as an example of the element in which an inductive pattern is formed on an inductor sheet, one or more inductive patterns may be formed on an inductor sheet, if necessary. Also, the inductor sheets may be laminated on the upper and/or lower surface of the laminate of the sheets on which the conductive patterns are formed.

Also, in addition to the meander-shaped inductive patterns, the shape of the inductive patterns may be diversely modified, for example, into a spiral or straight shape.

Although the element, which has the same conductive patterns as in the element of the embodiment 3 except that the inductive pattern instead of the resistive pattern is formed on the dummy sheet, has been described in the present embodiment, the inductive pattern may be formed instead of the resistive pattern on the laminated sheets of the embodiments 1 to 6 by the same manner as in the present embodiment.

### Embodiment 9

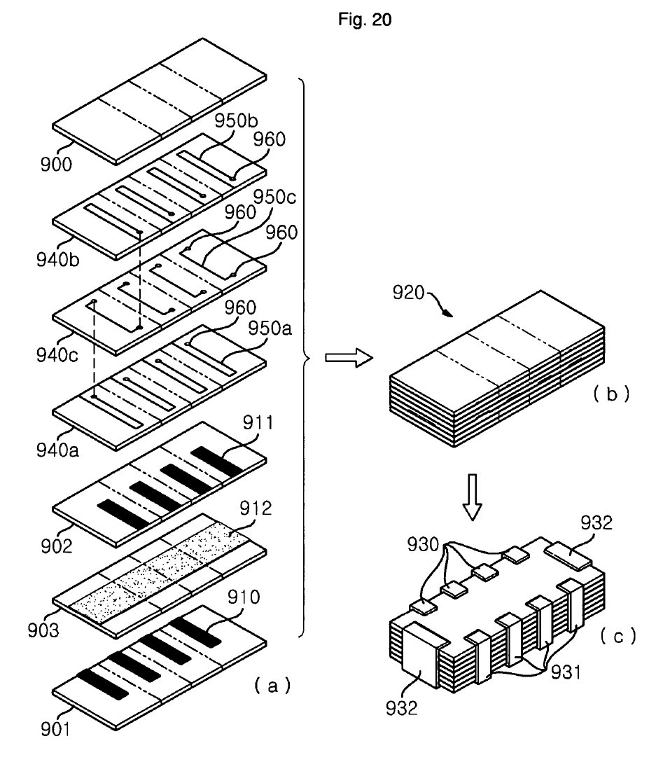

FIG. 20 is a view showing a manufacturing process of a laminated chip element combined with inductors according to the present embodiment 9, wherein four unit elements are integrally formed in a single chip element with inductive patterns formed on a plurality of inductor sheets using through holes.

First, first to third sheets 901 to 903, on the laminate of which inductor sheets are laminated, are manufactured by the same manner as in the embodiment 8.

Then, after molding inductor sheets as described in the embodiment 7, each inductive pattern is formed on each of the inductor sheets. That is, an inductive pattern 950a is formed on a first inductor sheet 940a in a predetermined shape, for example, a ‘U’ shape. Then, one end of the inductive pattern 950a is extended to an edge of the sheet to be connected to first external terminal, and a through hole is formed at the other end of the inductive pattern 950a through the first inductor sheet 940a. Similarly to the first inductor sheet 940a, an inductive pattern 950b is formed on a second inductor sheet 940b in a predetermined shape. One end of the inductive pattern 950b is extended to another edge of the sheet to be connected to second external terminal positioned opposite to the first external terminal, and a through hole is formed at the other end of the inductive pattern 950b through the second inductor sheet 940b. Next, an inductive pattern 950c is formed on a third inductor sheet 940c in a predetermined shape, and a through hole is formed at each of opposite ends of the inductive pattern 950c through the third inductor sheet 940c. The through holes formed in the third inductor sheet 940c are positioned corresponding to the through holes formed in the first and second inductor sheets 940a and 940b, respectively. The through holes of the inductor sheets are filled with conductive paste in order to connect the inductive patterns 950a to 950c to each other. At this time, in order to secure the connection between the inductive pattern 750 and the external terminals, metal pads (not shown) may be formed at positions corresponding to the one ends of the inductive patterns 950a and 950b to be connected to the first and second external terminals before arming the inductive patterns 950a and 950b.

In practice, after forming the through holes in the green sheet, the through holes may be filled with the conductive paste at the same time when the inductive patterns are printed with the conductive paste.

As shown in FIG. 20 (a), in the laminated chip element according to the present embodiment, after laminating the first to third sheets 901 to 903, the first to third inductor sheets 940a to 940c are laminated in order of the first inductor sheet 940a, the third inductor sheet 940c, the second inductor sheet 940b on the laminate of the first to third sheets 901 to 903, and then, a dummy sheet 900 is laminated thereon. When the first to third inductor sheets 940a to 940c are laminated, the inductive patterns of adjacent inductor sheets are connected to each other through the conductive paste filled in the corresponding through holes.

After the sheets are laminated as above, the laminated chip element is completed by compressing, cutting, baking out, and sintering the laminate, and forming external terminals, by the same manner as in the previous embodiments.

A plurality of the third inductor sheets 940c may be interposed between the first and second inductor sheets 940a and 940b, one ends of which are connected to the external terminals as input and output terminals, respectively. By controlling the number of the third inductor sheets 940c, it is possible to easily obtain the desired inductance.

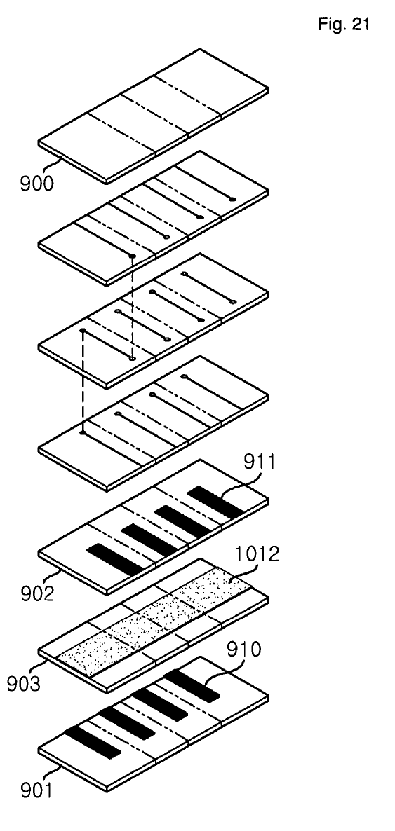

Although the inductive pattern is formed in a winding shape in the present embodiment, the shape of the inductive pattern may be diversely modified. For example, the inductive pattern on each inductor sheet may be formed into a straight shape, as shown in FIG. 21. That is, FIG. 21 is an exploded perspective view of a modified example, in which the inductive patterns are simplified as a straight shape, of the laminated chip element according to the embodiment 9. Such a laminated chip element may be more simply manufactured.

Although the element, which has the same conductive patterns as in the element of the embodiment 3 except that the inductive pattern instead of the resistive pattern is formed on the dummy sheet, has been described in the present embodiment, the inductive pattern may be formed instead of the resistive pattern on the laminated sheets of the embodiments 1 to 6 by the same manner as in the present embodiment.

### Embodiment 10

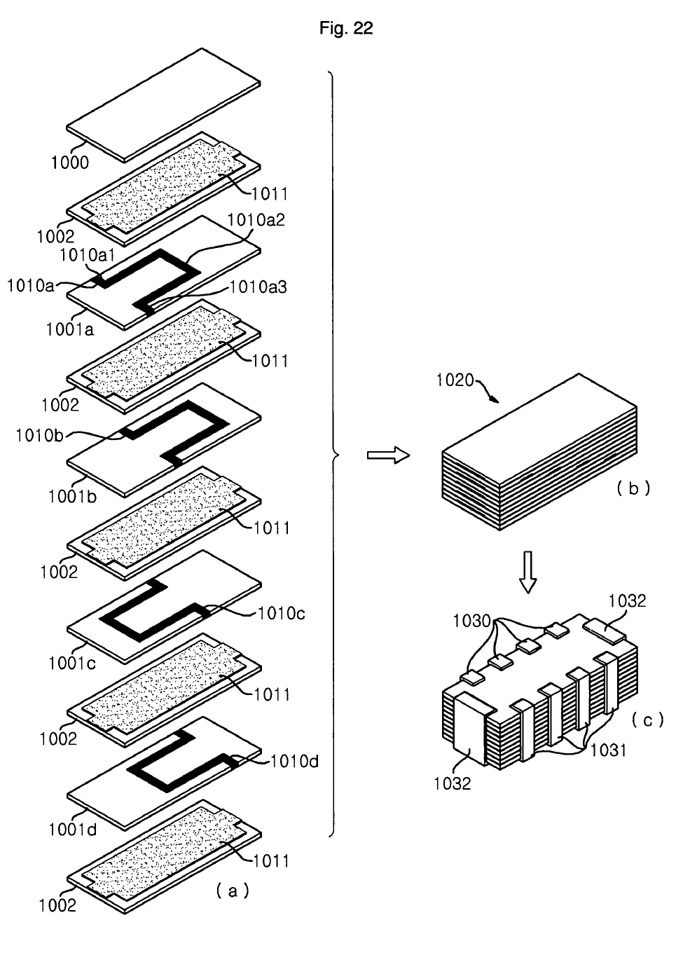

FIGS. 22 to 24 are views for explaining a laminated chip element according to the embodiment 10 of the present invention.

Referring to FIG. 22 showing a manufacturing process of the laminated chip element according to the present embodiment, a plurality of unit elements, for example, four unit elements are integrally formed in a single chip element.

Green sheets or a desired element are manufactured by the same manner as in the embodiment 1. Particularly, a ferrite green sheet may be used as a green sheet in the present embodiment.

Conductive patterns are formed on the green sheets manufactured as above by printing the conductive patterns with conductive paste of Ag, Pt, Pd, or the like, for example, by a screen printing method using screens of internal electrode patterns that are previously designed. That is, referring to FIG. 22 (a), a first conductive pattern 1010a consisting of first to third portions 1010a1 to 1010a3 is formed on a first sheet 1001a for a first one of the unit elements. The first and third portions 1010a1 and 1010a3 are spaced apart from each other in a direction of both opposite ends of the sheet, and the second portion 1010a2 connects the first and third portions 1010a1 and 1010a3 to each other. The second portion 1010a2 is formed in a predetermined shape, such as a ‘U’ shape, beyond the boundaries of the unit elements so that the first conductive pattern 1010a has a predetermined inductance. A second conductive pattern 1011 is formed on a second sheet 1002 in a transverse direction of both the opposite ends of the first sheet 1001a. A pair of the first and second sheets 1001a and 1002 may be laminated to form a single chip element.

In order to form four unit elements independent of each other into a single chip element, additional first sheets 1001b to 1001d for second to fourth ones of the unit elements are manufactured by forming first conductive patterns 1010b to 1010d on the respective green sheets by the same manner as in the first sheet 1001a. However, the first and third portions of the first conductive patterns 1010a to 1010d are positioned within the boundaries of the corresponding unit elements, respectively. That is, pairs of the first and third portions of the first conductive patterns 1010a to 1010d are spaced from each other in the transverse direction of both the opposite ends of the first sheet in order to be connected to corresponding first and second external terminals 1030 and 1031.

In the laminated chip element according to the present embodiment, the first sheets 1001a to 1001d and the second sheets 1002 are laminated so that each of the first sheets 1001a to 1001d is interposed between the two second sheets 1002, and then, a dummy sheet 1000 for protecting the conductive pattern of the uppermost sheet is laminated thereon, as shown in FIG. 22 (a). Instead of the dummy sheet 1000, an insulated pattern or layer may be formed on the uppermost sheet of the laminate.

After the sheets are laminated as above, the laminated chip element is completed by compressing, cutting, baking out, and sintering the laminate, and forming the external terminals, by the same manner as in the previous embodiments.

Accordingly, as shown in FIG. 22 (c), four pairs of the first and second external terminals 1030 and 1031 as input and output terminals and a third external terminal 1032 as a can terminal (ground electrode) are formed on the chip element. The first and third portions of the first conductive patterns 1010a to 1010d for each unit element are connected to the corresponding first and second external terminals 1030 and 1031, while both opposite ends of the second conductive patterns 1011 are connected to the third external terminal 1032. Alternatively, any one end of the second conductive patterns 1011 may be connected to the third external terminal. The portions of the conductive patterns which are not to be connected to the corresponding external terminals may be formed on the corresponding sheets in spaced relation with edges of the sheets.

In result, in the laminated chip element of the present embodiment in which the four unit elements are integrally formed, the first sheets for the respective unit elements are laminated between the second sheets. Since the first conductive patterns 1010a to 1010d for the respective unit elements are formed on the first sheets different from each other, each of the first conductive patterns 1010a to 1010d may be formed in an elongate shape beyond the boundaries of the unit elements. Thus, even though the respective unit elements have the elongate conductive patterns, the chip element according to the present invention may be manufactured to be compact.

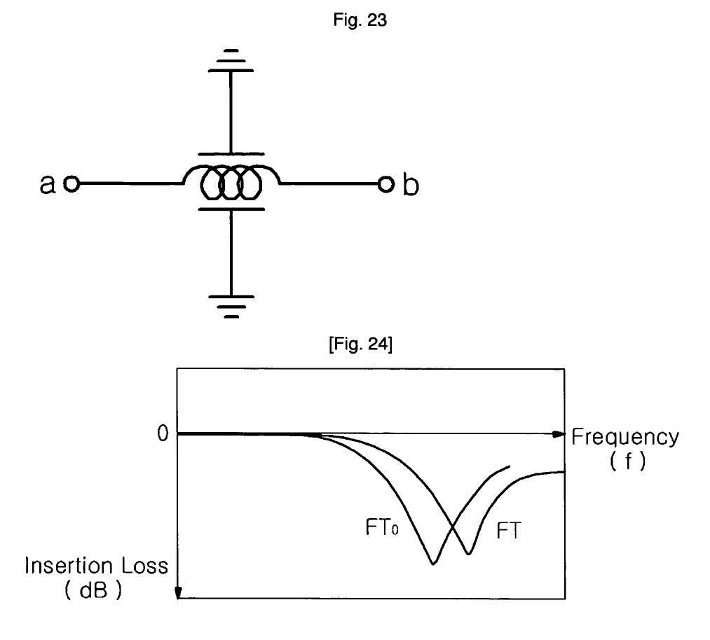

In the element shown in FIG. 22, each of the first conductive patterns 1010a to 1101d is interposed between the two second conductive patterns 1011. FIG. 23 shows an equivalent circuit diagram of the unit element according to a pair of the first and second sheets in the laminated chip element having the structure shown in FIG. 22. In the circuit diagram, the input and output terminals a and b are the first and second external terminals 1030 and 1031 connected to the first and third portions of the first conductive pattern 1010a, and the common terminal (ground electrode) is the third external terminal 1032 connected to both the opposite ends of the second conductive pattern 1011.

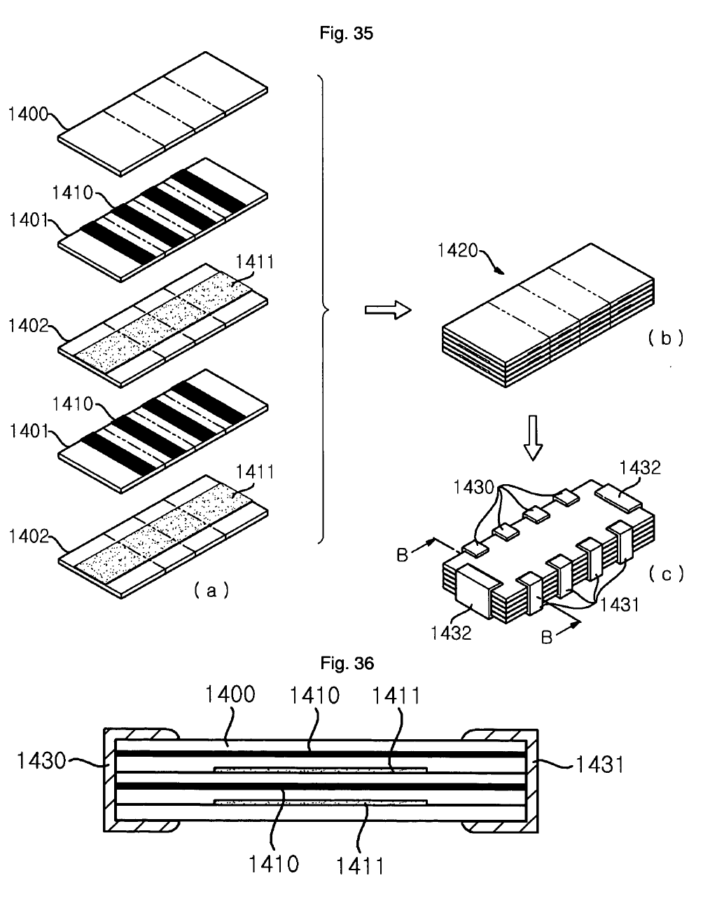

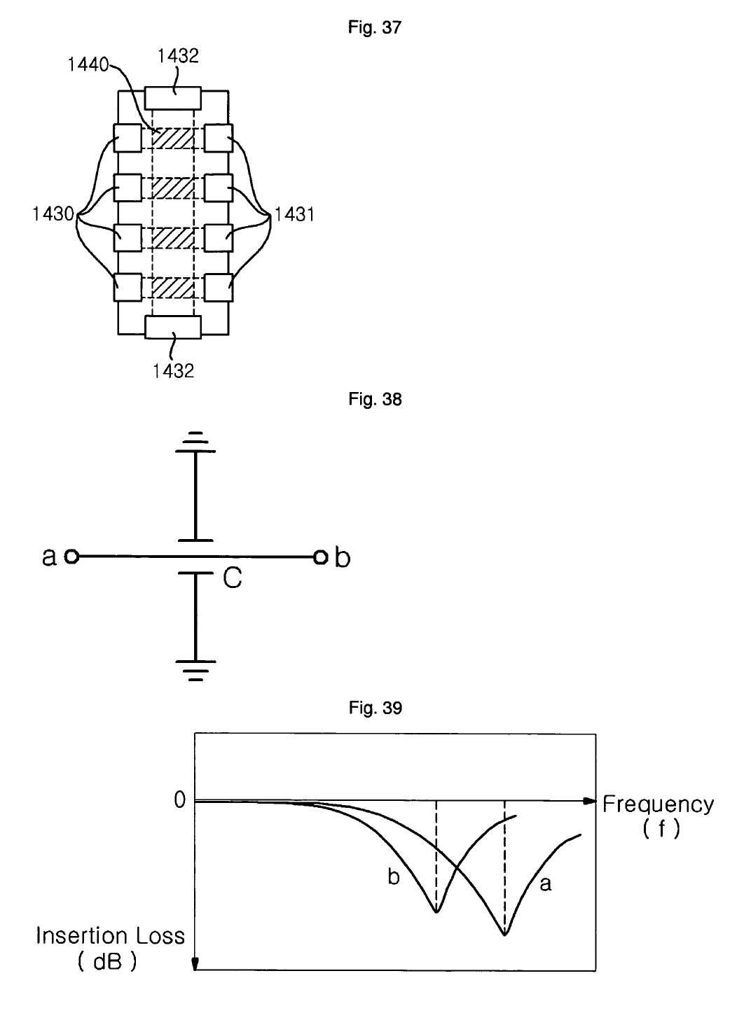

In the chip element shown in FIG. 22, the first conductive pattern is designed in the form of the elongate shape so that signal line is elongated in order to provide an inductor in the signal line in series. Accordingly, since a portion in which currents flowing in the signal line and a ground line have the same direction is elongated, a resonant frequency FT₀ of the chip element according to the present embodiment is lower than a resonant frequency FT of the conventional feedthrough element shown in FIG. 35, as shown in FIG. 24. In the laminated chip element according to the present embodiment, the noise removal property may be improved since an equivalent inductance of the signal line is increased, and then, an absolute value of the insertion loss is more increased.

### Embodiment 11

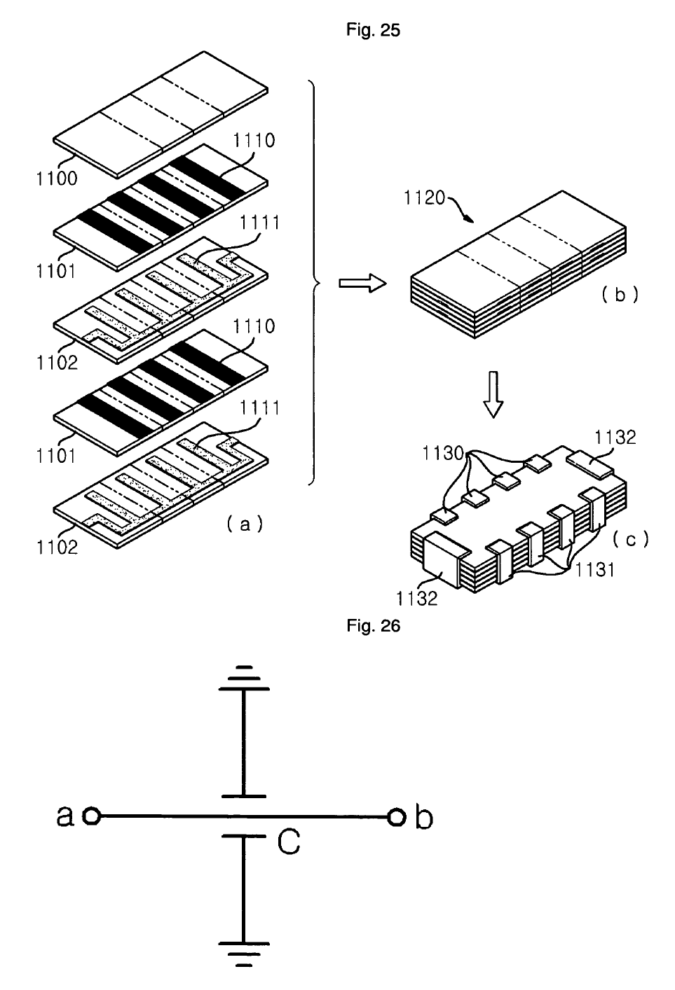

The present embodiment 11 shown in FIGS. 25 to 28 is directed to a laminated chip element which makes it possible to change an equivalent inductance according to a direction of a current flowing through input and output terminals by modifying a shape of a conductive pattern connected to a common terminal.

FIG. 25 is a view showing a manufacturing process of the laminated chip element according to the present embodiment, wherein four unit elements are integrally formed in a single chip element.

Green sheets for a desired element are manufactured by the same manner as in the embodiment 1. Particularly, a ferrite green sheet may be used as a green sheet in the present embodiment.

Conductive patterns are formed on the green sheets manufactured as above by printing the conductive patterns with conductive paste of Ag, Pt, Pd, or the like, for example, by a screen printing method using screens of internal electrode patterns that are previously designed. That is, a first conductive pattern 1110 is formed on a first sheet 1101 and extended in a direction of both opposite edges of the first sheet 1101. A second conductive pattern 1111 is formed on a second sheet 1102 in the same direction of the first conductive pattern 1110. Both opposite ends of the first conductive pattern 1110 are extended to both edges of the sheet 1101 to be connected to first and second external terminals 1130 and 1131, which are input and output terminals, while one end of the second conductive pattern 1111 is extended to be connected to the common terminal at one or two points. The portions of the conductive patterns which are not to be connected to the corresponding external terminals nay be not extended to the edges of the sheets.

When a plurality of unit elements, for example, four unit elements are integrally formed in the laminated chip element, a plurality of pairs of the first and second conductive patterns 1110 and 1111 are formed in parallel with each other on the first and second sheets 1101 and 1102. Each of the first conductive patterns 1110 is formed independently within a range of each of the unit elements, into which the chip element is divided by two-dot chain lines. However, it is preferable that the one ends of a plurality of the second conductive patterns 1111 be connected to each other, and then, connected to the common terminal. To this end, as shown in FIG. 25 (a), a plurality of the second conductive patterns 1111 each of which is formed in the same direction of the first conductive pattern 1110 are connected to each other at the one ends thereof, and then, both outermost ones of the second conductive patterns 1111 are extended to be connected to a third external terminal 1132. Alternatively, any one of both the outermost second conductive patterns 1111 may be extended to be connected to the third external terminal.

Two of the first sheets 1101 and two of the second sheet 1102 are alternately laminated on each other, and then, a dummy sheet 1100 is laminated thereon. Although the two first sheets and the two second sheets are alternately laminated in the present embodiment, the number of laminations of the first and second sheets is not limited thereto. Then, the laminated chip element is completed by compressing, cutting, baking out, and sintering the laminate, and forming the external terminals, by the same manner as in the previous embodiments.

FIG. 26 shows an equivalent circuit diagram of the unit element in the laminated chip element according to the present embodiment. In the circuit diagram, the input and output terminals a and b are the first and second external terminals 1130 and 1131 connected to both the opposite ends of the first conductive pattern 1110, and the common terminal (ground electrode) is the third external terminal 1132 connected to both the opposite ends of the second conductive pattern 1111.

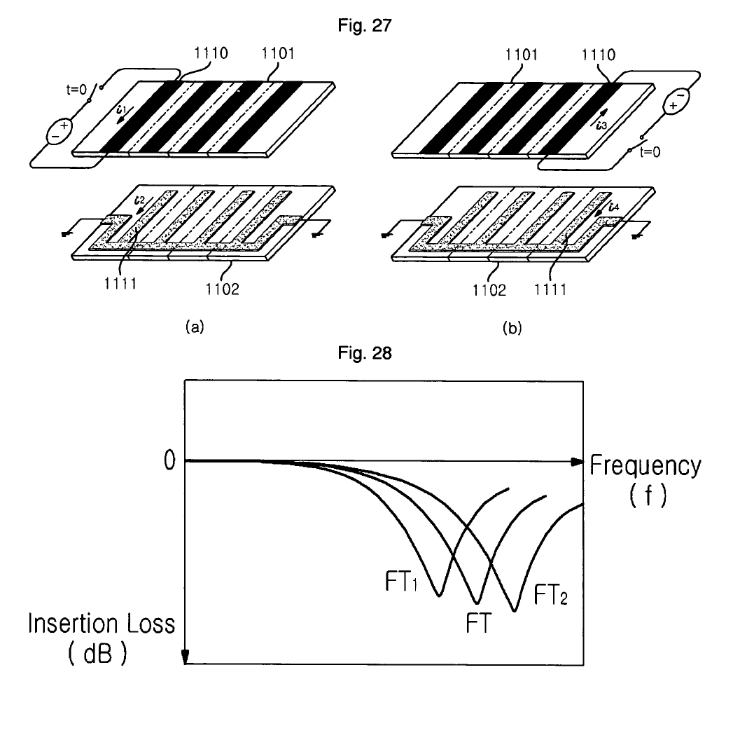

Referring to FIG. 27 for explaining an operation of the laminated chip element according to the present embodiment 11, it can be easily understood that an equivalent inductance varies according to the direction of a current flowing through the first and second external terminals of the laminated chip element. If a voltage is applied to the first conductive pattern 1110 used as a signal line as shown in FIG. 27 (a), a current i₁ flows left downward. If a voltage is applied to the first conductive pattern 1110 used as a signal line as shown in FIG. 27 (b), a current i₃ flows right upward. Since the one ends of the second conductive patterns 1111, i.e., the ground line, are connected to the common terminal, currents i₂ and i₄ always flow left downward in the second conductive patterns 1111 in both cases of FIGS. 27 (a) and (b). Therefore, an equivalent inductance of the laminated chip element shown in FIG. 27 (a) is maximized since the directions of currents i₁ and i₂ flowing in the signal and ground lines are the same, whereas an equivalent inductance of the laminated chip element shown in FIG. 27 (b) is minimized since the directions of currents i₃ and i₄ flowing in the signal and ground lines are opposite to each other.

In addition, although not shown in the figure, if two of the second sheets 1102 are interposed between the two first sheets 1101, since a passage for a high frequency noise signal to flow widens, the insertion loss property is improved.

FIG. 28 is a graph showing frequency properties of the laminated chip element according to the embodiment 11 of the present invention and the laminated chip element according to the prior art. As described above, the equivalent inductance varies according to the direction of the current flowing in the signal line of the laminated chip element of the present embodiment. That is, since the equivalent inductance of the leftmost unit element in FIG. 26 is maximized, a resonant frequency FT₁ of the leftmost unit element is lower than the resonant frequency FT of the conventional feedthrough element. On the other hand, since the equivalent inductance of the rightmost unit element in FIG. 26 is minimized, a resonant frequency FT₂ of the rightmost unit element is higher than the resonant frequency FT of the conventional feedthrough element. Thus, a direction of the element, i.e., a directions of the input and output signals, should be indicated on an outer surface of the element.

In the laminated chip element according to the present embodiment, since the inductance of the element may be controlled according to the direction of the current flowing through the first and second external terminals, it is possible to obtain the element with a desired frequency property.

### Embodiment 12

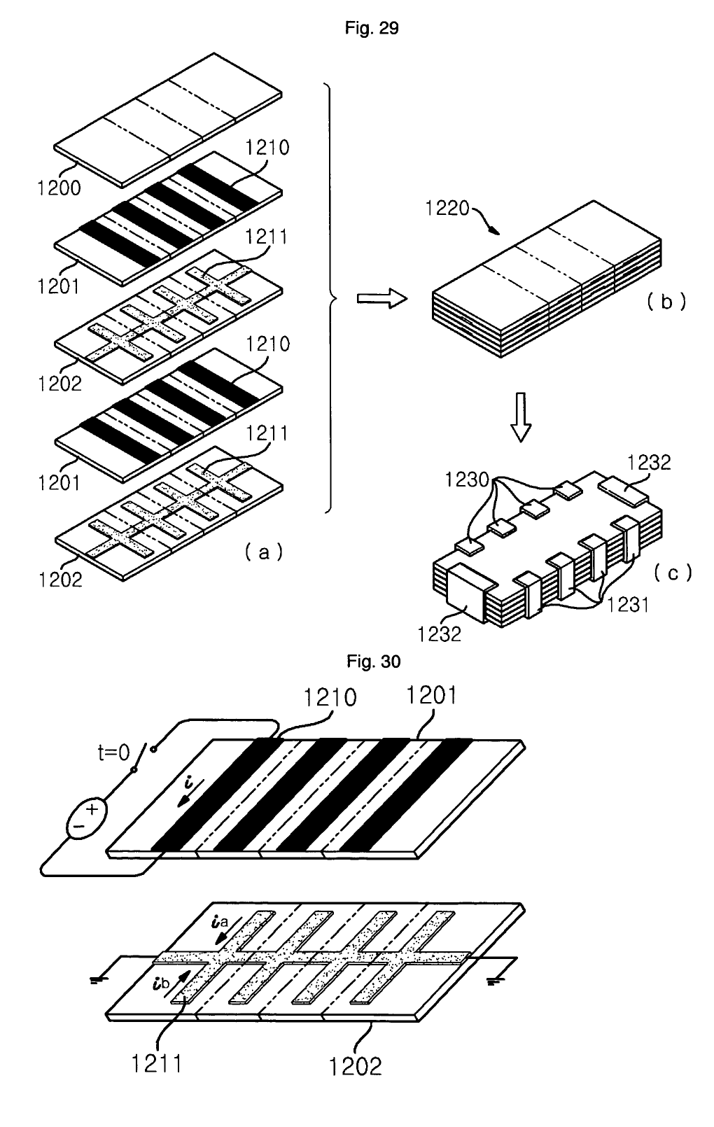

As a modified example of the embodiment 11, the present embodiment 12 shown in FIGS. 29 to 31 is directed to a laminated chip element which has the high insertion loss and can be employed when frequency range of noise in a circuit is low.

The embodiment 12 is similar to the embodiment 11 in a structure except second conductive patterns 1211. That is, a first conductive pattern 1210 is formed on a first sheet 1201 and is extended in a direction of both opposite edges of the first sheet 1201. The second conductive pattern 1211 is formed on a second sheet 1202 in the same direction of the first conductive pattern 1210. In addition, the second conductive pattern 1211 is formed so that the center of the second conductive pattern 1211 is extended to be connected to a third external terminal 1231, i.e., a common terminal. That is, two opposite points in the center of the second conductive pattern 1211 are extended to be connected to the third external terminal 1231. Alternatively, only a point in the center of the second conductive pattern 1211 may be extended to be connected to the third external terminal 1231. Particularly, as shown in FIG. 29 (a), when a plurality of unit elements are integrally formed in parallel with each other into a single chip element, the respective second conductive patterns 1211 may be formed in a cross shape (+) in order to be connected to each other at its center and to the third external terminal 1231. The portions of the conductive patterns which are not to be connected to the corresponding external terminals may be not extended to the edges of the sheets.

The first and second sheets 1201 and 1202 and a dummy sheet 1200 are laminated by the same manner as in the embodiment 11. Then, the laminated chip element is completed by compressing, cutting, baking out, and sintering the laminate, and forming the external terminals, by the same manner as in the previous embodiments.

Referring to FIG. 30, an operation of the laminated chip element according to the present embodiment 12 will be explained. A voltage is applied to the first and second external terminals connected to both opposite ends of any one of the first conductive patterns 1210 used as a signal line so that a current i flows left downward in the first conductive pattern 1210, as shown in FIG. 30. Since the center of the second conductive pattern 1211 used as a ground line is connected to a ground terminal, i.e., the common terminal, currents iₐ and i_{b} flow in the second conductive pattern 1211 toward the center thereof. Therefore, an equivalent inductance at a portion in which the current iₐ flows is maximized since the directions of the currents i and iₐ flowing in the signal and ground lines are the same, whereas an equivalent inductance at a portion in which the current i_{b} flows is minimized since the directions of the currents i and i_{b} flowing in the signal and ground lines are opposite to each other. Thus, since both the equivalent inductances are mutually cancelled out, there is only an inductance at a center line of the second conductive pattern 1211, wherein the center line may consist of portions for connecting the second conductive patterns to each other and portions for connecting outermost ones of the second conductive patterns to the third external terminal.

In addition, although not shown in the figure, if a plurality of the second sheets 1202 are interposed between the two first sheets 1201, since a passage for a high frequency noise signal to flow widens, the insertion loss property is improved.

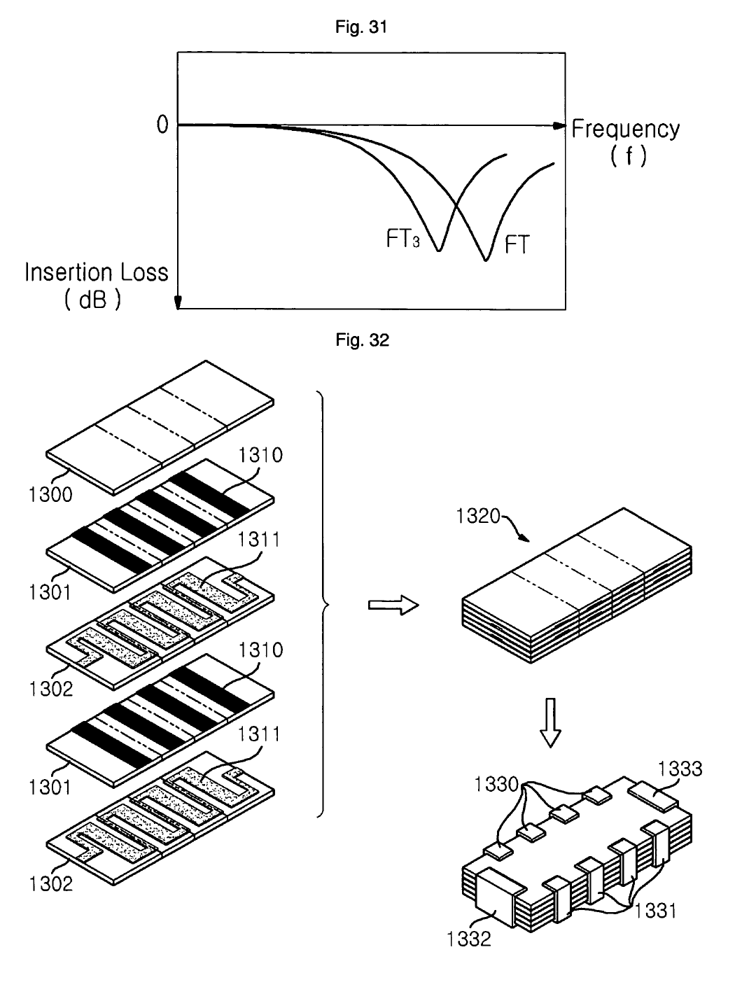

FIG. 31 is a graph showing frequency properties of the laminated chip element according to the embodiment 12 of the present invention and the laminated chip element according to the prior art. As shown in FIG. 31, a resonant frequency FT₃ of the laminated chip element according to the embodiment 12 is lower than the resonant frequency FT of the conventional feedthrough element. It is the reason why the inductance at the center line of the second conductive patterns 1211 remains in the element shown in FIG. 29, as compared with the conventional feedthrough element wherein there is almost no equivalent inductance since the signal and ground lines cross each other at 90 degrees. Therefore, while maintaining the insertion loss and the noise removal property on a level with that of the conventional feedthrough element, the laminated chip element according to the embodiment 12 may be preferably employed when a frequency range of noise in a circuit is low.

Although the center of the second conductive pattern 1211 is connected to the common terminal in the present embodiment, in order for the element to have a desired frequency property, another appropriate position between both opposite ends of the second conductive pattern 1211 may be connected to the common terminal.

### Embodiment 13

As a modified example of the embodiments 11 and 12, the present embodiment 13 shown in FIGS. 32 to 34 is directed to a laminated chip element which has a low resonant frequency while maintaining the noise removal property, insertion loss, or the like. That is, the present embodiment 13 is directed to the laminated chip element which has an increased equivalent inductance in order to obtain the foregoing property. To this end, a conductive pattern connected to a common terminal is modified so that currents flowing signal and ground lines are always the same in direction regardless of a direction of the current flowing through input and output terminals.

The embodiment 13 is similar to the embodiments 11 and 12 in a structure except second conductive patterns 1311.

As shown in FIG. 32 (a), a first conductive pattern 1310 is formed on a first sheet 1301 and is extended in a direction of both opposite edges of the first sheet 1301. The second conductive pattern 1311 is armed on a second sheet 1302 in the same direction of the first conductive pattern 1310. In addition, the second conductive pattern 1311 is formed so that both opposite ends of the second conductive pattern 1311 are extended to be connected to a third external terminal 1332, i.e., a common terminal. When a plurality of unit elements, for example, four unit elements are integrally formed in parallel with each other in the laminated chip element, both opposite ends of two outermost ones of the second conductive patterns 1311 are extended to opposite edges of the second sheet 1302 to be connected to the third external terminal 1332, and ends of the other second conductive patterns are connected to the opposite ends of the adjacent second conductive patterns one to one. The portions of the conductive patterns which are not to be connected to the corresponding external terminals may be not extended to the edges of the sheets.

The first and second sheets 1301 and 1302 and a dummy sheet 1300 are laminated by the same manner as in the embodiments 11 and 12. Then, the laminated chip element is completed by compressing, cutting, baking out, and sintering the laminate, and forming the external terminals, by the same manner as in the previous embodiments.

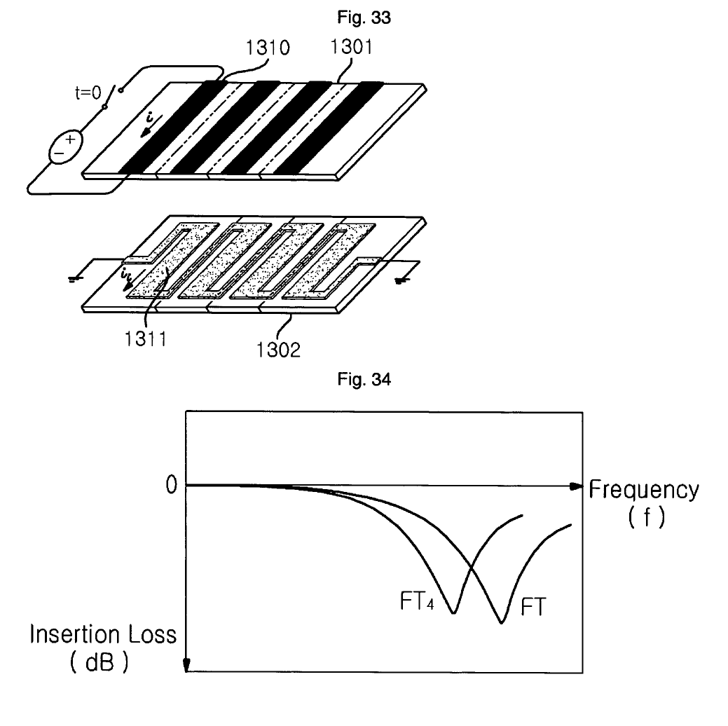

Referring to FIG. 33, an operation of the laminated chip element according to the present embodiment 13 will be explained. A voltage is applied to the first and second external terminals connected to both opposite ends of any one of the first conductive patterns 1310 used as a signal line so that a current i flows left downward in the first conductive pattern 1310 as shown in FIG. 33. At this time, magnetic field is generated around the first conductive pattern 1310, so that an induced current iᵢ with the same direction of the current i is generated in the second conductive pattern 1311 positioned just above and/or below the first conductive pattern 1310. Therefore, since the currents i and iᵢ are the same in a direction, an equivalent inductance is maximized. As shown in FIG. 34 showing frequency properties of the laminated chip element according to the embodiment 13 of the present invention and the laminated chip element according to the prior art, a resonant frequency FT₄ of the laminated chip element according to the embodiment 13 is lower than the resonant frequency FT of the conventional feedthrough element. Accordingly, while maintaining the noise removal property, insertion loss, or the like on a level with that of the conventional feedthrough element, the laminated chip element according to the embodiment 13 may be preferably employed when a frequency range of noise in a circuit is low.

In addition, although not shown in the figure, if a plurality of the second sheets 1302 are interposed between the two first sheets 1301, since a passage for a high frequency noise signal to flow widens, the insertion loss property is improved.

In the previous embodiments 1 to 13, the green sheets for a varistor may be manufactured. If some of the conductive patterns are formed by printing them with resistive paste of Ni—Cr, RuO₂, or the like, the laminated chip element is the varistor element combined with the resistor. Thus, when over-voltage is applied to a circuit, the current in the element flows out to the common terminal so that the circuit can be protected from the over-voltage conditions. Further, since some of the conductive patterns may be formed of metal material of Ag, Pt, Pd, or the like in order to increase conductivity or resistive material of Ni—Cr, RuO₂, or the like in order to decrease conductivity, the impedance matching of the circuit can be easily performed. Alternatively, if the conductive patterns and the resistive pattern are formed on the green sheets for a PTC thermistor or a NTC thermistor, the laminated chip element is a thermistor combined with a resistor, which can protect the circuit from over-current or rapid temperature variation.

### INDUSTRIAL APPLICABILITY

The laminated chip element of the present invention makes it possible to control capacitance, resistance and/or inductance to desired values and to improve the frequency properties such as the noise removal, insertion loss, or the like. In addition, the laminated chip element of the present invention can effectively protect main electronic parts such as semiconductor integrated circuits from static electricity in addition to over-voltage.

Furthermore, the present invention makes it possible to manufacture the laminated chip element combined with a resistor or inductor to be compact and light without additional processes. Furthermore, since the laminated chip element of the present invention can be simply manufactured without additional processes, costs for manufacturing process can be reduced.

The scope of the present invention is not limited to the embodiments described and illustrated above but is defined by the appended claims. It will be apparent that those skilled in the art can make various modifications and changes thereto within the scope of the invention defined by the claims. Therefore, the true scope of the present invention should be defined by the technical spirit of the appended claims.

The present application contains subject matter related to Korean Patent Application Nos. KR 10-2003-0052561 and 10-2003-0052562, filed in the Korean Intellectual Property Office on Jul. 30, 2003, the entire contents of which are incorporated herein by reference.

1. A laminated chip element comprising a plurality of unit elements, comprising:
at least one first sheet on which a plurality of pairs of first and second conductive patterns are formed, each pair of the first and second conductive patterns being spaced apart from each other and formed at both ends of the first sheet, each pair of the first and second conductive patterns being arranged in each of the unit elements;
at least one second sheet on which a third conductive pattern is formed, the third conductive pattern being formed over the unit elements in a transverse direction of both the ends of the first sheet; and
a plurality of resistive patterns formed corresponding to the unit elements on the first and second sheets,
wherein one ends of the first and second conductive patterns are connected to first and second external terminals, which are input and output terminals, respectively, at least one end of the third conductive pattern is connected to a third external terminal, which is a common terminal, both ends of each of the resistive patterns are connected to the first and second external terminals, respectively, the first and second sheets are alternately laminated, and a protective insulation layer is formed on the uppermost one of the laminated sheets.

2. A laminated chip element comprising a plurality of unit elements, comprising:
at least one first sheet on which a plurality of pairs of first and second conductive patterns are formed, each pair of the first and second conductive patterns being spaced apart from each other and formed at both ends of the first sheet, each pair of the first and second conductive patterns being arranged in each of the unit elements;
at least one second sheet on which a third conductive pattern is formed, the third conductive pattern being formed over the unit elements in a transverse direction of both the ends of the first sheet; and
a plurality of inductive patterns formed corresponding to the unit elements on the first and second sheets,
wherein one ends of the first and second conductive patterns are connected to first and second external terminals, which are input and output terminals, respectively, at least one end of the third conductive pattern is connected to a third external terminal, which is a common terminal, both ends of each of the inductive patterns are connected to the first and second external terminals, respectively, the first and second sheets are alternately laminated, and a protective insulation layer is formed on the uppermost one of the laminated sheets.

3. A laminated chip element comprising a plurality of unit elements, comprising:
at least one first sheet on which a plurality of pairs of first and second conductive patterns are formed, each pair of the first and second conductive patterns being spaced apart from each other and formed at both ends of the first sheet, each pair of the first and second conductive patterns being arranged in each of the unit elements;
at least one second sheet on which a third conductive pattern is formed, the third conductive pattern consisting of first and second portions which are spaced apart from each other and formed over the unit elements in a transverse direction of both the ends of the first sheet; and
a plurality of resistive patterns formed corresponding to the unit elements on the first and second sheets,
wherein one ends of the first and second conductive patterns are connected to first and second external terminals, which are input and output terminals, respectively, both opposite ends of the first and second portions of the third conductive pattern are connected to third and fourth external terminals, which are common terminals, respectively, both ends of each of the resistive patterns are connected to the first and second external terminals, respectively, the first and second sheets are alternately laminated, and a protective insulation layer is formed on the uppermost one of the laminated sheets.

4. A laminated chip element comprising a plurality of unit elements, comprising:
at least one first sheet on which a plurality of pairs of first and second conductive patterns are formed, each pair of the first and second conductive patterns being spaced apart from each other and formed at both ends of the first sheet, each pair of the first and second conductive patterns being arranged in each of the unit elements;
at least one second sheet on which a third conductive pattern is formed, the third conductive pattern consisting of first and second portions which are spaced apart from each other and formed over the unit elements in a transverse direction of both the ends of the first sheet; and
a plurality of inductive patterns formed corresponding to the unit elements on the first and second sheets,
wherein one ends of the first and second conductive patterns are connected to first and second external terminals, which are input and output terminals, respectively, both opposite ends of the first and second portions of the third conductive pattern are connected to third and fourth external terminals, which are common terminals, respectively, both ends of each of the inductive patterns are connected to the first and second external terminals, respectively, the first and second sheets are alternately laminated, and a protective insulation layer is formed on the uppermost one of the laminated sheets.

5. A laminated chip element comprising a plurality of unit elements, comprising:
at least one first sheet on which a plurality of first conductive patterns are formed in a direction of both ends of the first sheet, each of the first conductive patterns being arranged in each of the unit elements;
at least one second sheet on which a plurality of second conductive patterns are formed in the same direction as the first conductive patterns, each of the second conductive patterns being arranged in each of the unit elements;
at least one third sheet on which a third conductive pattern is formed, the third conductive pattern being formed over the unit elements in a transverse direction of both the ends of the first sheet; and
a plurality of resistive patterns formed corresponding to the unit elements on the first to third sheets,
wherein both opposite ends of the first and second conductive patterns are connected to first and second external terminals, which are input and output terminals, respectively, at least one end of the third conductive pattern is connected to a third external terminal, which is a common terminal, both ends of each of the resistive patterns are connected to the first and second external terminals, respectively, the first to third sheets are laminated so that at least one of the third sheet is interposed between the first and second sheets, and a protective insulation layer is formed on the uppermost one of the laminated sheets.

6. A laminated chip element comprising a plurality of unit elements, comprising:
at least one first sheet on which a plurality of first conductive patterns are formed in a direction of both ends of the first sheet, each of the first conductive patterns being arranged in each of the unit elements;
at least one second sheet on which a plurality of second conductive patterns are formed in the same direction as the first conductive patterns, each of the second conductive patterns being arranged in each of the unit elements;
at least one third sheet on which a third conductive pattern is formed, the third conductive pattern being formed over the unit elements in a transverse direction of both the ends of the first sheet; and
a plurality of inductive patterns formed corresponding to the unit elements on the first to third sheets,
wherein both opposite ends of the first and second conductive patterns are connected to first and second external terminals, which are input and output terminals, respectively, at least one end of the third conductive pattern is connected to a third external terminal, which is a common terminal, both ends of each of the inductive patterns are connected to the first and second external terminals, respectively, the first to third sheets are laminated so that at least one of the third sheet is interposed between the first and second sheets, and a protective insulation layer is formed on the uppermost one of the laminated sheets.

7. A laminated chip element comprising a plurality of unit elements, comprising:
at least one first sheet on which a plurality of first conductive patterns are formed in a direction of both ends of the first sheet, each of the first conductive patterns being arranged in each of the unit elements;
at least one second sheet on which a plurality of second conductive patterns are formed in the same direction as the first conductive patterns, each of the second conductive patterns being arranged in each of the unit elements;
at least one third sheet on which a third conductive pattern is formed, the third conductive pattern being formed over the unit elements in a transverse direction of both the ends of the first sheet;
at least one fourth sheet on which a fourth conductive pattern is formed, the fourth conductive pattern being formed over the unit elements in a transverse direction of both the ends of the first sheet; and
a plurality of resistive patterns formed corresponding to the unit elements on the first to fourth sheets,
wherein both opposite ends of the first and second conductive patterns are connected to first and second external terminals, which are input and output terminals, respectively, both opposite ends of the third and fourth conductive patterns are connected to third and fourth external terminals, which are common terminals, respectively, both ends of each of the resistive patterns are connected to the first and second external terminals, respectively, the first to fourth sheets are laminated so that the third and fourth sheets are interposed between the first and second sheets, and a protective insulation layer is formed on the uppermost one of the laminated sheets.

8. A laminated chip element comprising a plurality of unit elements, comprising:
at least one first sheet on which a plurality of first conductive patterns are formed in a direction of both ends of the first sheet, each of the first conductive patterns being arranged in each of the unit elements;
at least one second sheet on which a plurality of second conductive patterns are formed in the same direction as the first conductive patterns, each of the second conductive patterns being arranged in each of the unit elements;
at least one third sheet on which a third conductive pattern is formed, the third conductive pattern being formed over the unit elements in a transverse direction of both the ends of the first sheet;
at least one fourth sheet on which a fourth conductive pattern is formed, the fourth conductive pattern being formed over the unit elements in a transverse direction of both the ends of the first sheet; and
a plurality of inductive patterns formed corresponding to the unit elements on the first to fourth sheets,
wherein both opposite ends of the first and second conductive patterns are connected to first and second external terminals, which are input and output terminals, respectively, both opposite ends of the third and fourth conductive patterns are connected to third and fourth external terminals, which are common terminals, respectively, both ends of each of the inductive patterns are connected to the first and second external terminals, respectively, the first to fourth sheets are laminated so that the third and fourth sheets are interposed between the first and second sheets, and a protective insulation layer is formed on the uppermost one of the laminated sheets.

9. A laminated chip element comprising a plurality of unit elements, comprising:
at least one first sheet on which a plurality of first conductive patterns are formed in a direction of both ends of the first sheet, each of the first conductive patterns being arranged in each of the unit elements;
at least one second sheet on which a plurality of second conductive patterns are formed in the same direction as the first conductive patterns, each of the second conductive patterns being arranged in each of the unit elements;
at least one third sheet on which a third conductive pattern is formed, the third conductive pattern comprising a plurality of first portions formed in the same direction as the first conductive patterns and a second portion connected to one ends of the first portions, each of the first portions being arranged in each of the unit elements, the second portion being formed over the unit elements in a transverse direction of both the ends of the first sheet; and
a plurality of resistive patterns formed corresponding to the unit elements on the first to third sheets,
wherein both opposite ends of the first and second conductive patterns are connected to first and second external terminals, which are input and output terminals, respectively, at least one end of the second portion of the third conductive pattern is connected to a third external terminal, which is a common terminal, both ends of each of the resistive patterns are connected to the first and second external terminals, respectively, the first to third sheets are laminated so that at least one of the third sheet is interposed between the first and second sheets, and a protective insulation layer is formed on the uppermost one of the laminated sheets.

10. A laminated chip element comprising a plurality of unit elements, comprising:
at least one first sheet on which a plurality of first conductive patterns are formed in a direction of both ends of the first sheet, each of the first conductive patterns being arranged in each of the unit elements;
at least one second sheet on which a plurality of second conductive patterns are formed in the same direction as the first conductive patterns, each of the second conductive patterns being arranged in each of the unit elements;
at least one third sheet on which a third conductive pattern is formed, the third conductive pattern comprising a plurality of first portions formed in the same direction as the first conductive patterns and a second portion connected to one ends of the first portions, each of the first portions being arranged in each of the unit elements, the second portion being formed over the unit elements in a transverse direction of both the ends of the first sheet; and
a plurality of inductive patterns formed corresponding to the unit elements on the first to third sheets,
wherein both opposite ends of the first and second conductive patterns are connected to first and second external terminals, which are input and output terminals, respectively, at least one end of the second portion of the third conductive pattern is connected to a third external terminal, which is a common terminal, both ends of each of the inductive patterns are connected to the first and second external terminals, respectively, the first to third sheets are laminated so that at least one of the third sheet is interposed between the first and second sheets, and a protective insulation layer is formed on the uppermost one of the laminated sheets.

11. A laminated chip element comprising a plurality of unit elements, comprising:
at least one first sheet on which a plurality of first conductive patterns are formed, each of the first conductive patterns consisting of first to third portions, the first and second portions being spaced apart from each other and formed at both ends of the first sheet, the third portion being spaced apart from the first and second portions and formed in a transverse direction of both the ends of the first sheet, each of the first conductive patterns being arranged in each of the unit elements;
at least one second sheet on which a plurality of second conductive patterns are formed, each of the second conductive patterns consisting of fourth and fifth portions spaced from each other, the fourth portion partially overlapping with the first and third portions, the fifth portion partially overlapping with the second and third portions, each of the second conductive patterns being arranged in each of the unit elements; and
a plurality of resistive patterns formed corresponding to the unit elements on the first and second sheets,
wherein one ends of the first and second portions are connected to first and second external terminals, which are input and output terminals, respectively, the third portions are connected to each other over the unit elements, at least one end of the connected third portions is connected to a third external terminal, which is a common terminal, both ends of each of the resistive patterns are connected to the first and second external terminals, respectively, the first and second sheets are alternately laminated, and a protective insulation layer is formed on the uppermost one of the laminated sheets.

12. A laminated chip element comprising a plurality of unit elements, comprising:
at least one first sheet on which a plurality of first conductive patterns are formed, each of the first conductive patterns consisting of first to third portions, the first and second portions being spaced apart from each other and formed at both ends of the first sheet, the third portion being spaced apart from the first and second portions and formed in a transverse direction of both the ends of the first sheet, each of the first conductive patterns being arranged in each of the unit elements;
at least one second sheet on which a plurality of second conductive patterns are formed, each of the second conductive patterns consisting of fourth and fifth portions spaced from each other, the fourth portion partially overlapping with the first and third portions, the fifth portion partially overlapping with the second and third portions, each of the second conductive patterns being arranged in each of the unit elements; and
a plurality of inductive patterns formed corresponding to the unit elements on the first and second sheets,
wherein one ends of the first and second portions are connected to first and second external terminals, which are input and output terminals, respectively, the third portions are connected to each other over the unit elements, at least one end of the connected third portions is connected to a third external terminal, which is a common terminal, both ends of each of the inductive patterns are connected to the first and second external terminals, respectively, the first and second sheets are alternately laminated, and a protective insulation layer is formed on the uppermost one of the laminated sheets.

13. The laminated chip element according to claim 1, wherein areas of overlapping portions between the conductive patterns differ from each other.

14. The laminated chip element according to claim 1, wherein pairs of metal pads are formed to be spaced each other, and each of the resistive patterns is formed so that the resistive pattern connects a pair of the metal pads to each other.

15. The laminated chip element according to claim 2, wherein pairs of metal pads are formed to be spaced each other, and each of the inductive patterns is formed so that the inductive pattern connects a pair of the metal pads to each other.

16. The laminated chip element according to claim 1, wherein the protective insulation layer includes epoxy or glass.

17. The laminated chip element according to claim 2, wherein some of the inductive patterns of the unit elements are formed on an upper surface of the laminated chip element, and the other of the inductive patterns of the unit elements are formed on a lower surface of the laminated chip element.

18. The laminated chip element according to claim 2, wherein the inductive pattern is spiral, an insulated bridge is formed in a radial direction across the spiral inductive pattern, and a bridge pattern for extending a central end of the inductive pattern to an outside thereof is formed on the insulated bridge.

19. The laminated chip element according to claim 2, wherein a ferrite layer is form on the laminated chip element, and the inductive pattern is formed on the ferrite layer.

20. The laminated chip element according to claim 2, wherein the inductive pattern includes resistive material, such as Ni—Cr, RuO₂.

21. The laminated chip element according to claim 2, wherein a plurality of inductor sheets are further laminated, at least one of the inductive patterns are formed on each of the inductor sheets, and both ends of the respective inductive patterns are connected to the corresponding first and second external terminals.

22. The laminated chip element according to claim 2, wherein a plurality of inductor sheets are further laminated, an inductive pattern is formed on each of the inductor sheets, the inductive patterns are connected to each other in series through holes formed in the inductor sheets, both ends of the connected inductive patterns are connected to the first and second external terminals, respectively.

23. A laminated chip element, comprising:
at least one first sheet on which a first conductive pattern is formed, the first conductive pattern consisting of first to third portions, the first and third portions being spaced apart from each other at both ends of the first sheet, the second portion connecting the first and third portions to each other to have a predetermined inductance; and
at least one second sheet on which a second conductive pattern is formed in a transverse direction of both the ends of the first sheet;
wherein the first and third portions are connected to first and second external terminals, respectively, at least one ends of the second conductive pattern is connected to a third external terminal, a plurality of the first sheets and the second sheets are alternately laminated on each other, and the first and third portions of the first conductive patterns formed on the respective first sheets are connected to the respective first and second external terminals.

24. A laminated chip element, comprising:
at least one first sheet on which a first conductive pattern is formed in a direction of both ends of the first sheet; and
at least one second sheet on which a second conductive pattern is formed in the same direction as the first conductive pattern;
wherein both ends of the first conductive pattern are connected to first and second external terminals, respectively, a terminal connecting portion of the second conductive pattern is connected to a third external terminal, and the first and second sheets are laminated.

25. The laminated chip element according to claim 24, wherein the terminal connecting portion is an end of the second conductive pattern.

26. The laminated chip element according to claim 24, wherein the terminal connecting portion is an intermediate portion of the second conductive pattern.

27. The laminated chip element according to claim 24, wherein the terminal connecting portion is both opposite ends of the second conductive pattern.

28. The laminated chip element according to claim 24, wherein a plurality of the first and second conductive patterns are formed in parallel with each other on the corresponding sheets, the terminal connecting portion of outermost one of the second conductive patterns is connected to the third external terminal, the terminal connecting portions of the other second conductive patterns are connected to the terminal connecting portions of the adjacent second conductive patterns, and both ends of each of the first conductive patterns are connected to the first and second external terminals for each unit element.
